(19) United States
(12) Patent Application Publication
(10) Pub. No.: US 2024/0321581 A1
(43) Pub. Date: Sep. 26, 2024

(54) NANOSTRUCTURE FIELD-EFFECT TRANSISTOR DEVICE AND METHODS OF FORMING

(71) Applicant: Taiwan Semiconductor Manufacturing Co., Ltd., Hsinchu (TW)

(72) Inventors: Tzu-Ging Lin, Kaohsiung City (TW); Shun-Hui Yang, Chiayi City (TW); Yen Ju Chen, Hsinchu (TW); Yun-Chen Wu, Hsinchu (TW); Chun-Liang Lai, Hsinchu (TW)

(21) Appl. No.: 18/360,447

(22) Filed: Jul. 27, 2023

Related U.S. Application Data
(60) Provisional application No. 63/491,587, filed on Mar. 22, 2023.

(51) Int. Cl. H01L 21/28; H01L 29/06; H01L 29/423; H01L 29/66; H01L 29/775

(52) U.S. Cl. CPC H01L 21/28123; H01L 29/0673; H01L 29/42392; H01L 29/66439; H01L 29/66545; H01L 29/775

(57) ABSTRACT

A method of forming a semiconductor device includes: forming a dummy gate structure over a first fin and around first channel regions that are disposed over the first fin; forming an interlayer dielectric (ILD) layer over the first fin around the dummy gate structure; replacing the dummy gate structure with a gate structure; forming a first dielectric plug and a second dielectric plug in the gate structure on opposing sides of the first fin, where the first and second dielectric plugs cut the gate structure into a plurality of segments separated from each other; removing a segment of the gate structure interposed between the first dielectric plug and the second dielectric plugs to expose the first channel regions; removing the exposed first channel regions, where after removing the exposed first channel regions, a recess is formed in the ILD layer; and filling the recess with a dielectric material.

### PRIORITY CLAIM AND CROSS-REFERENCE

This application claims priority to U.S. Provisional Patent Application No. 63/491,587, filed Mar. 22, 2023, entitled “Semiconductor Structure and Manufacturing Method Thereof,” which application is hereby incorporated by reference in its entirety.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A-5C, 6A-6C, 7A-7C, 8A, 8B, 9A, 9B, 10A, 10B, 11A, 11B, 12A, 12B, 13A-13C, 14A, 14B, 15A, 15B, 16A, 16B, 17A, 17B, 18A, 18B, and 19A-19C are various views of a nanostructure field-effect transistor (NSFET) device at various stages of manufacturing, in accordance with an embodiment.

FIGS. 20A and 20B illustrate alternative processing steps to form the NSFET device 100 at a certain stage of manufacturing, in accordance with an embodiment.

FIGS. 21A and 21B illustrate alternative processing steps to form the NSFET device 100 at a certain stage of manufacturing, in accordance with another embodiment.

FIGS. 22A and 22B together illustrate a flow chart of a method of forming a semiconductor device, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

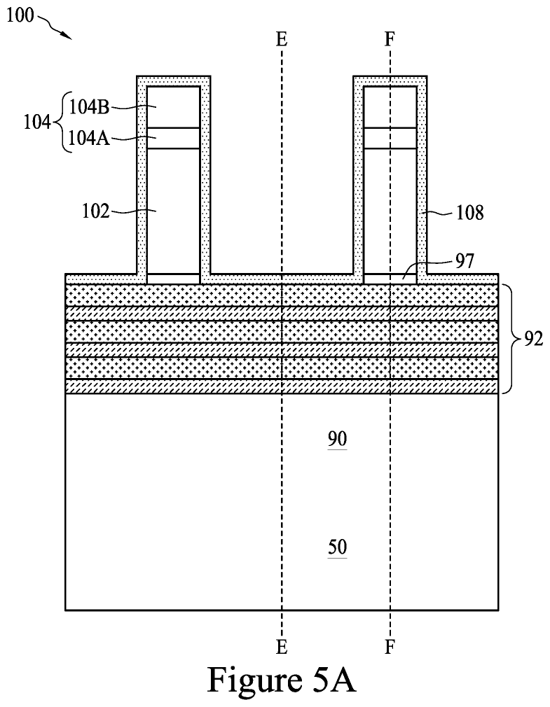

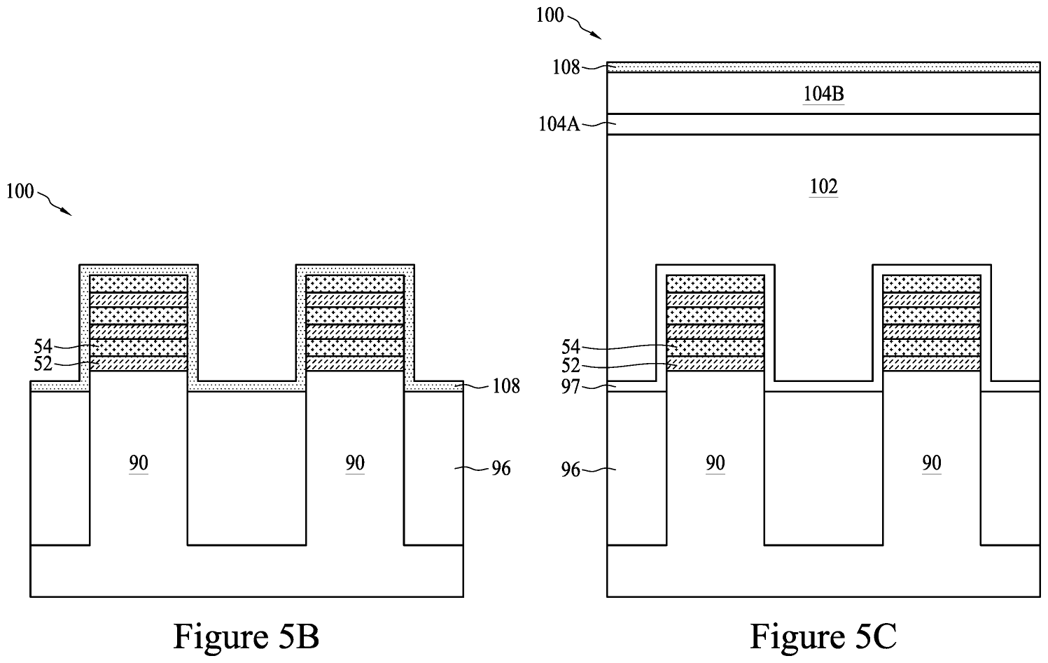

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise described, the same or similar reference numeral in different figures refer to the same or similar component formed by a same or similar formation process using a same or similar material(s). In addition, figures with the same numeral but different alphabets (e.g., FIGS. 5A-5C) illustrate different views of the NSFET device at the same stage of processing.

Embodiments of the present disclosure are discussed in the context of forming a nanostructure field-effect transistor (NSFET) device (e.g., nanosheet device, nanowire device). The principle of the disclosure may also be applied for forming contacts in other types of devices, such as fin field-effect transistor (FinFET) devices.

In accordance with some embodiments, dielectric plugs are formed by a Cut Metal Gate (CMG) process to cut a metal gate structure of an NSFET device, which metal gate structure is formed by a replacement gate process to replace a dummy gate structure. After the dielectric plugs are formed, a segment of the metal gate structure interposed between the dielectric plugs are removed to expose the channel regions (e.g., nanosheets, or nanowires) of the NSFET device. The exposed channel regions are then removed and replaced by a dielectric material to form a dielectric structure by a Continuous Metal On-Diffusion Edge (CMODE) process (also referred to as a Cut Metal on-Diffusion Edge (CMODE) process). By performing the CMODE process after the metal gate structure is formed, less deformation in the NSFET device is achieved, which in turn results in less stress release of the epitaxial source/drain, thereby achieving better carrier mobility in the channel regions. In addition, the disclosed CMODE process provides higher tolerance to inaccuracy in the patterns of the hard mask layer used for removing the segment of the metal gate structure.

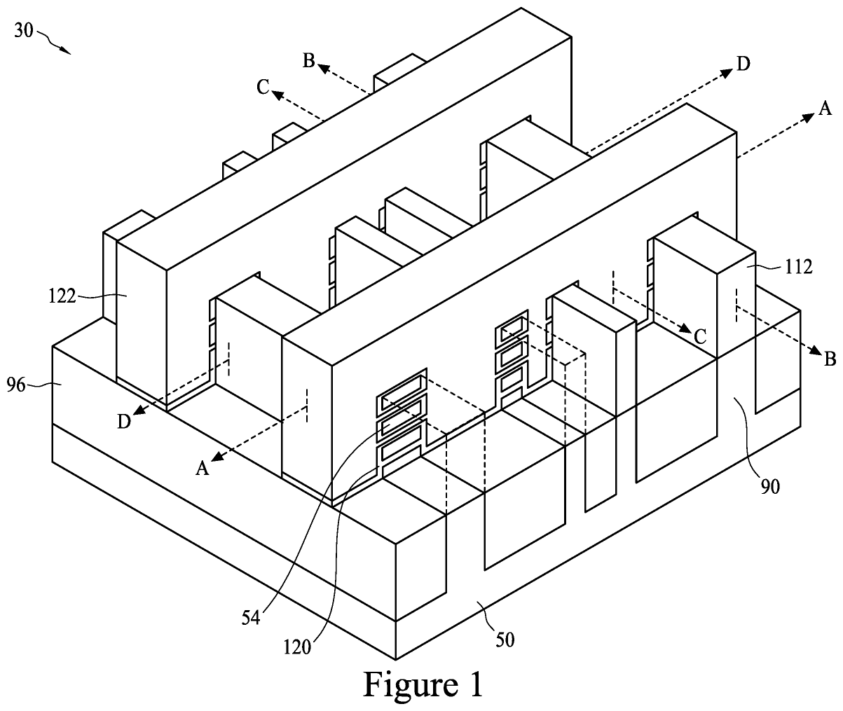

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Isolation regions 96 are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the gate electrode 122 and in a direction, for example, perpendicular to the direction of current flow between the source/drain regions 112 of the NSFET device 30. Cross-section B-B is perpendicular to cross-section A-A and is along a longitudinal axis of the fin 90 and in a direction of, for example, a current flow between the source/drain regions 112 of the NSFET device. Cross-section C-C is parallel to cross-section B-B and between two neighboring fins 90. Cross-section D-D is parallel to cross-section A-A and extends through source/drain regions 112 of the NSFET device. Subsequent figures may refer to these reference cross-sections for clarity.

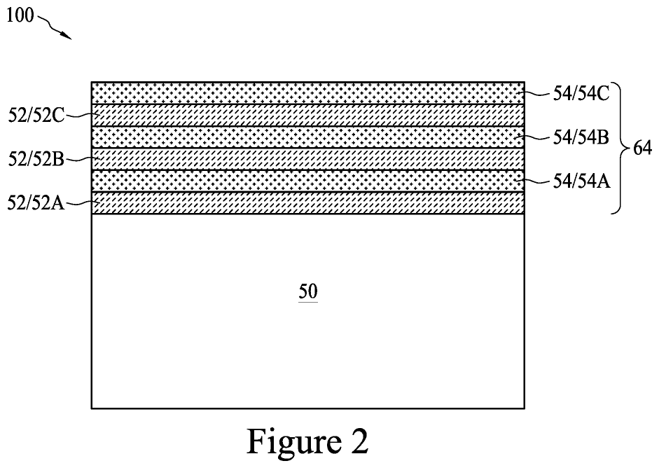

FIGS. 2, 3A, 3B, 4A, 4B, 5A-5C, 6A-6C, 7A-7C, 8A, 8B, 9A, 9B, 10A, 10B, 11A, 11B, 12A, 12B, 13A-13C, 14A, 14B, 15A, 15B, 16A, 16B, 17A, 17B, 18A, 18B, and 19A-19C are various views (e.g., cross-sectional view, top view) of a nanostructure field-effect transistor (NSFET) device 100 at various stages of manufacturing, in accordance with an embodiment.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the semiconductor materials illustrated in FIG. 2 are merely non-limiting examples. Other numbers of layers are also possible and are fully intended to be included within the scope of the present disclosure.

In some embodiments, the first semiconductor material 52 is an epitaxial material appropriate for forming channel regions of p-type FETs, such as silicon germanium (SiₓGe₁₋ₓ, where x can be in the range of 0 to 1), and the second semiconductor material 54 is an epitaxial material appropriate for forming channel regions of n-type FETs, such as silicon. The multi-layer stack 64 (which may also be referred to as an epitaxial material stack) will be patterned to form channel regions of an NSFET in subsequent processing. In particular, the multi-layer stack 64 will be patterned and etched to form horizontal nanostructures (e.g., nanosheets or nanowires), with the channel regions of the resulting NSFET including multiple horizontal nanostructures.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed.

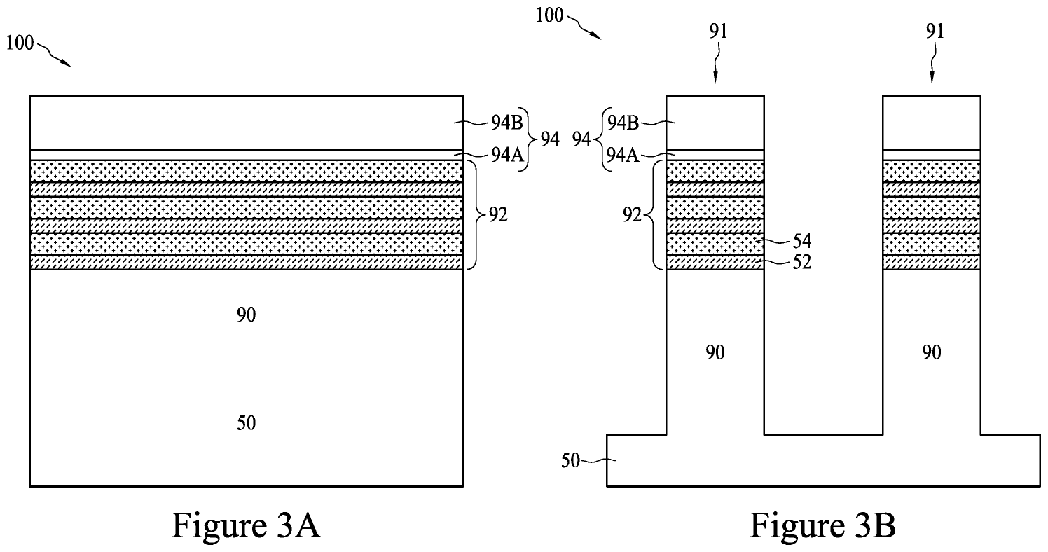

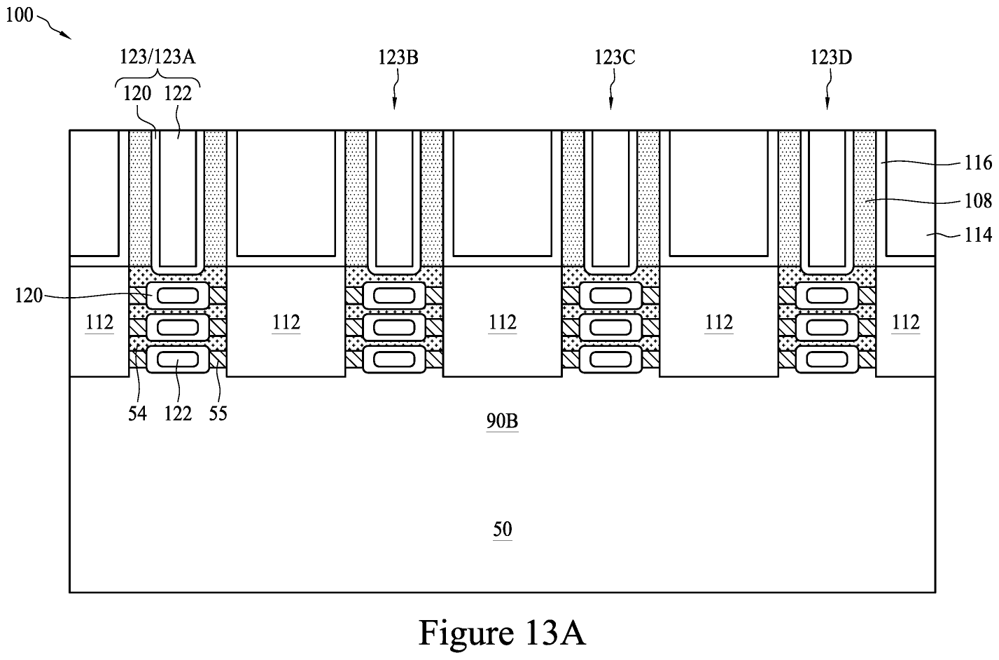

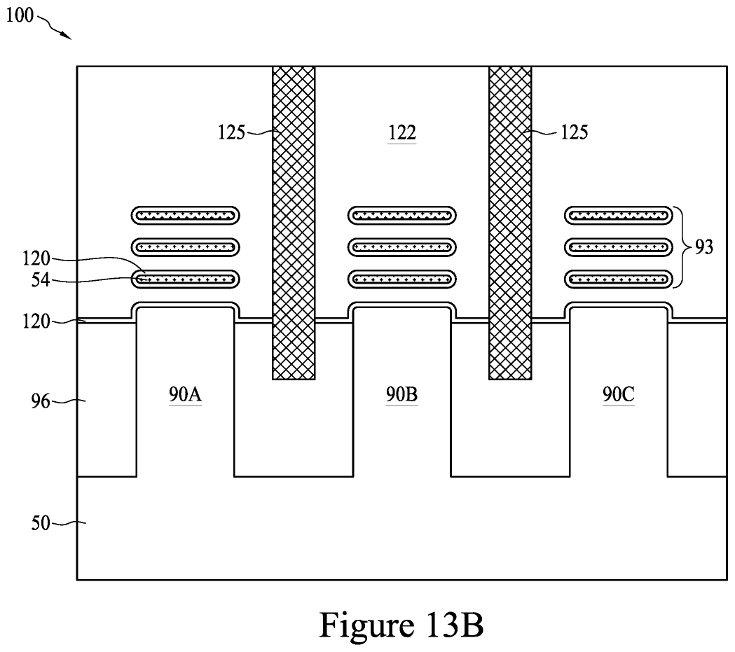

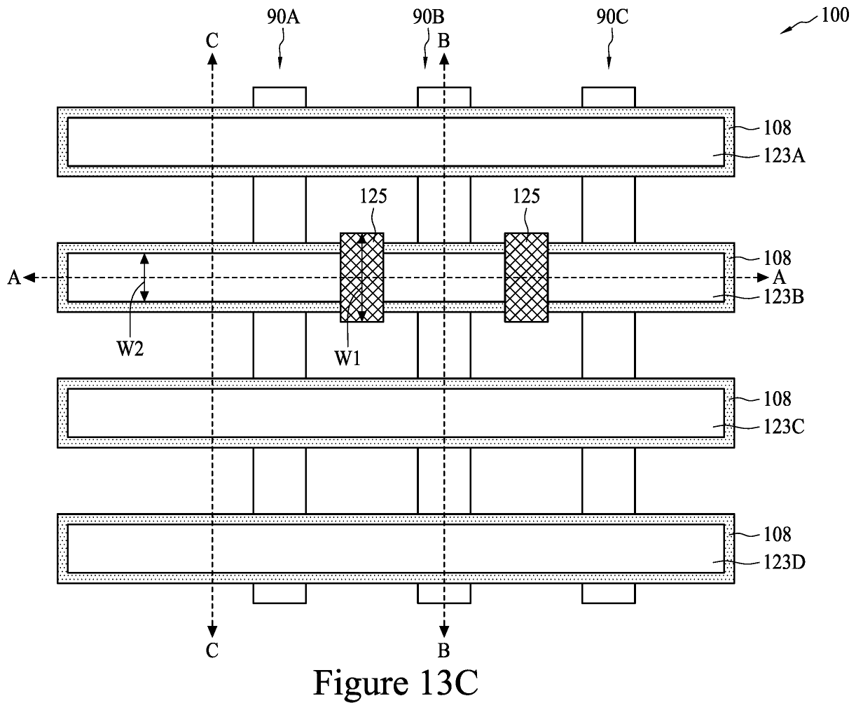

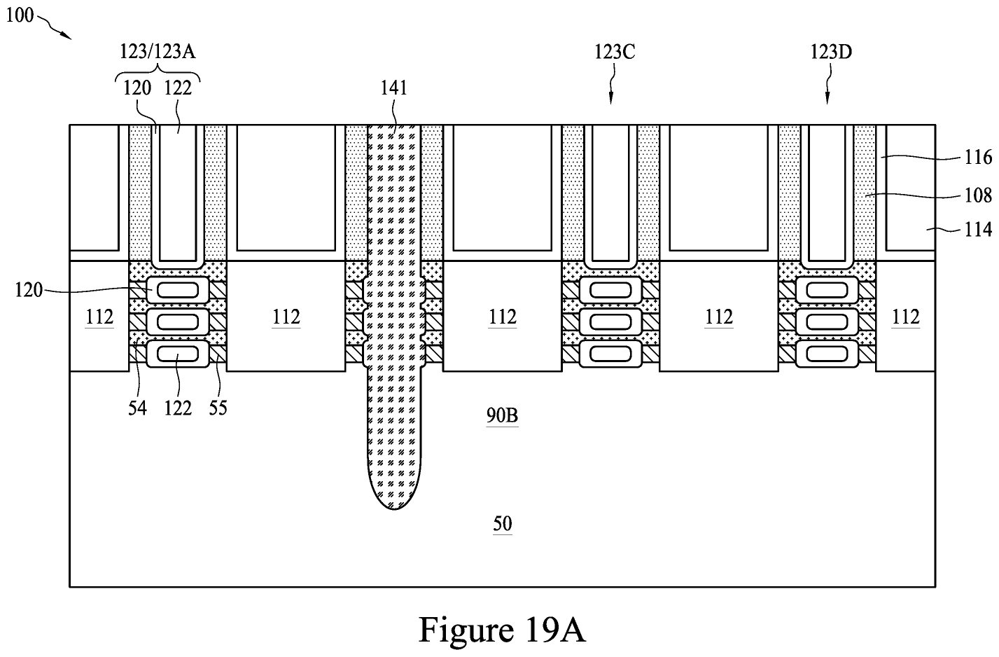

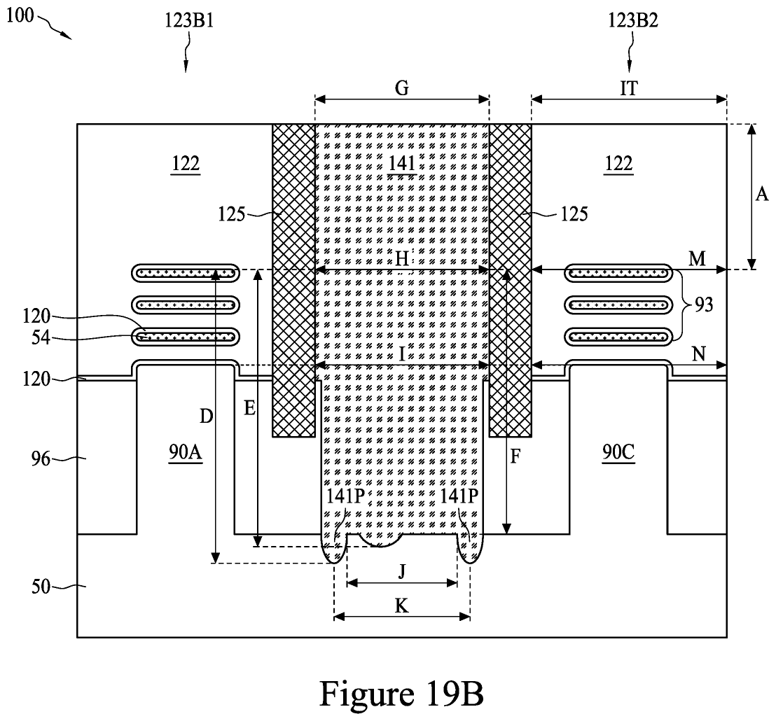

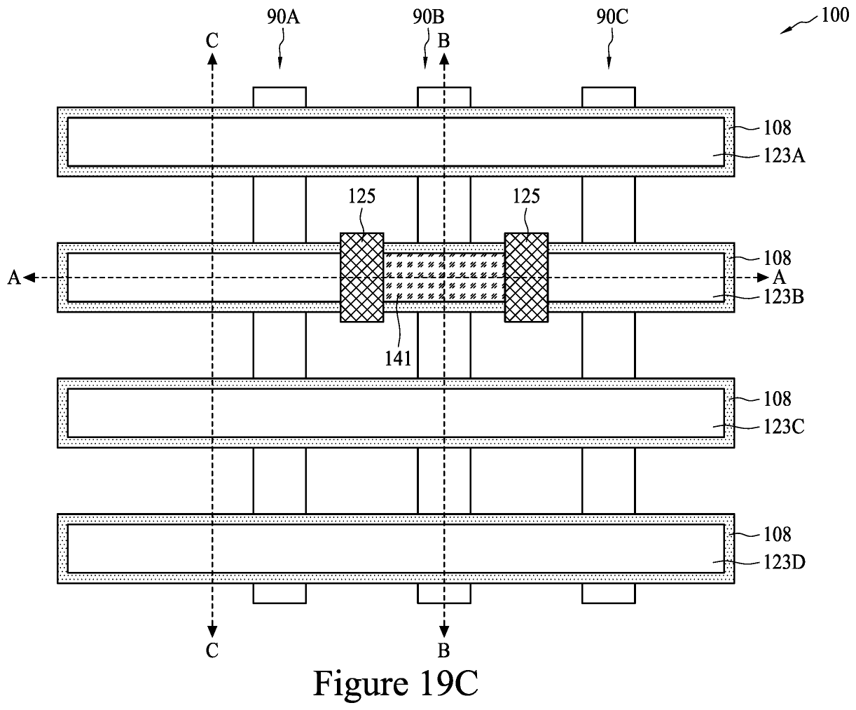

FIGS. 3A, 3B, 4A, 4B, 5A-5C, 6A-6C, 7A-7C, 8A, 8B, 9A, 9B, 10A, 10B, 11A, 11B, 12A, 12B, 13A-13C, 14A, 14B, 15A, 15B, 16A, 16B, 17A, 17B, 18A, 18B, and 19A-19C are various views (e.g., cross-sectional view, top view) of the NSFET device 100 at subsequent stages of manufacturing, in accordance with an embodiment. FIGS. 3A, 4A, 5A, 6A, 7A, 8A, 9A, 10A, 11A, 12A, 13A, 14A, 15A, 16A, 17A, 18A, and 19A are cross-sectional views along cross-section B-B in FIG. 1. FIGS. 3B, 4B, 5C, 6C, 7C, 8B, 9B, 10B, 11B, 12B, 13B, 14B, 15B, 16B, 17B, 18B, and 19B are cross-sectional views along cross-section A-A in FIG. 1. FIGS. 5B, 6B, and 7B are cross-sectional views along cross-section D-D in FIG. 1. FIGS. 13C and 19C are top view (e.g., plan view) of the NSFET device 100. The number of fins and the number of gate structures illustrated in the figures are merely a non-limiting example, it should be appreciated that other numbers of fins and other numbers of gate structures may also be formed.

In FIGS. 3A and 3B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etch process, such as a reactive ion etch (RIE), neutral beam etch (NBE), the like, or a combination thereof. The etching is an anisotropic etching process, in some embodiments. After the etching process, the patterned multi-layer stack 64 forms the layer stack 92, and the patterned substrate 50 forms the fin 90, as illustrated in FIGS. 3A and 3B. Therefore, in the illustrated embodiment, the layer stack 92 also includes alternating layers of the first semiconductor material 52 and the second semiconductor material 54, and the fin 90 is formed of a same material (e.g., silicon) as the substrate 50.

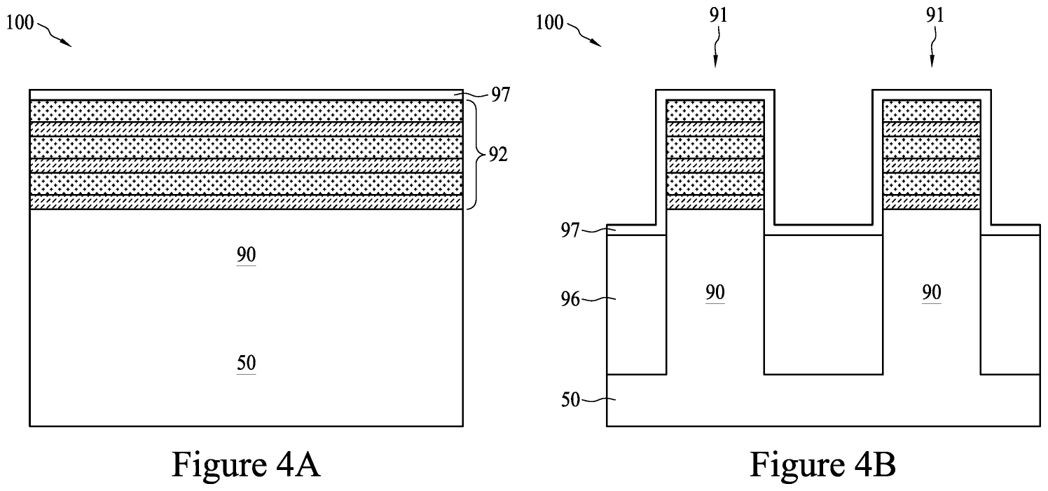

Next, in FIGS. 4A and 4B, Shallow Trench Isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material over the fin structures 91. In some embodiments, a planarization process such as a chemical mechanical polish (CMP), an etch back process, combinations thereof, or the like, may be utilized. The planarization process exposes the layer stacks 92 such that top surfaces of the layer stacks 92 and the insulation material are level after the planarization process is complete. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than the material of the fin 90 and the layer stack 92). For example, a chemical oxide removal with a suitable etchant such as dilute hydrofluoric (dHF) acid may be used.

Still referring to FIGS. 4A and 4B, a dummy dielectric layer 97 is formed over the layer stack 92 and over the STI regions 96. The dummy dielectric layer 97 may be, for example, silicon oxide, silicon nitride, a combination thereof, or the like, and may be deposited or thermally grown according to acceptable techniques. In an embodiment, a layer of silicon is conformally formed over the layer stack 92 and over the upper surface of the STI regions 96, and a thermal oxidization process is performed to convert the deposited silicon layer into an oxide layer as the dummy dielectric layer 97.

Next, in FIGS. 5A-5C, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by a CMP. The dummy gate layer may be a conductive material and may be selected from a group including amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other techniques known and used in the art. The dummy gate layer may be made of other materials that have a high etching selectivity from the STI regions 96.

Masks 104 are then formed over the dummy gate layer. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectrics 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. The dummy gate 102 and the dummy gate dielectric 97 are collectively referred to as dummy gate structure, in some embodiments.

Next, a gate spacer layer 108 is formed by conformally depositing an insulating material over the layer stacks 92, the STI regions 96, and the dummy gates 102. The insulating material may be silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

FIGS. 5B and 5C illustrate cross-sectional views of the NSFET device 100 in FIG. 5A along cross-sections E-E and F-F in FIG. 5A, respectively. The cross-sections E-E and F-F correspond to cross-sections D-D and A-A in FIG. 1, respectively.

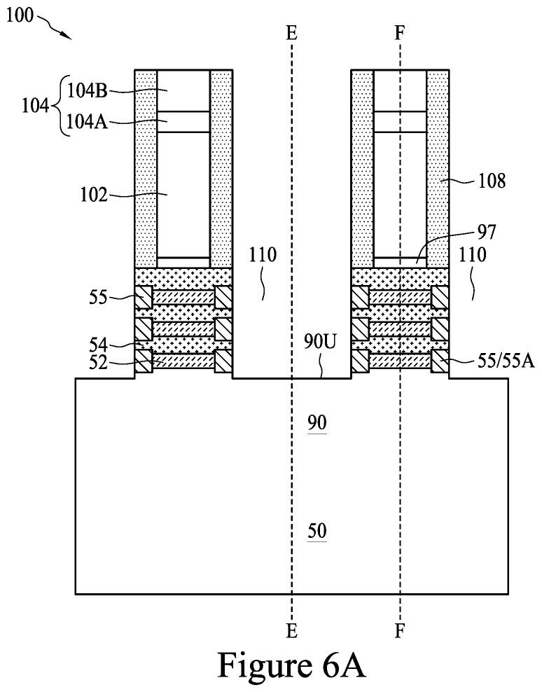

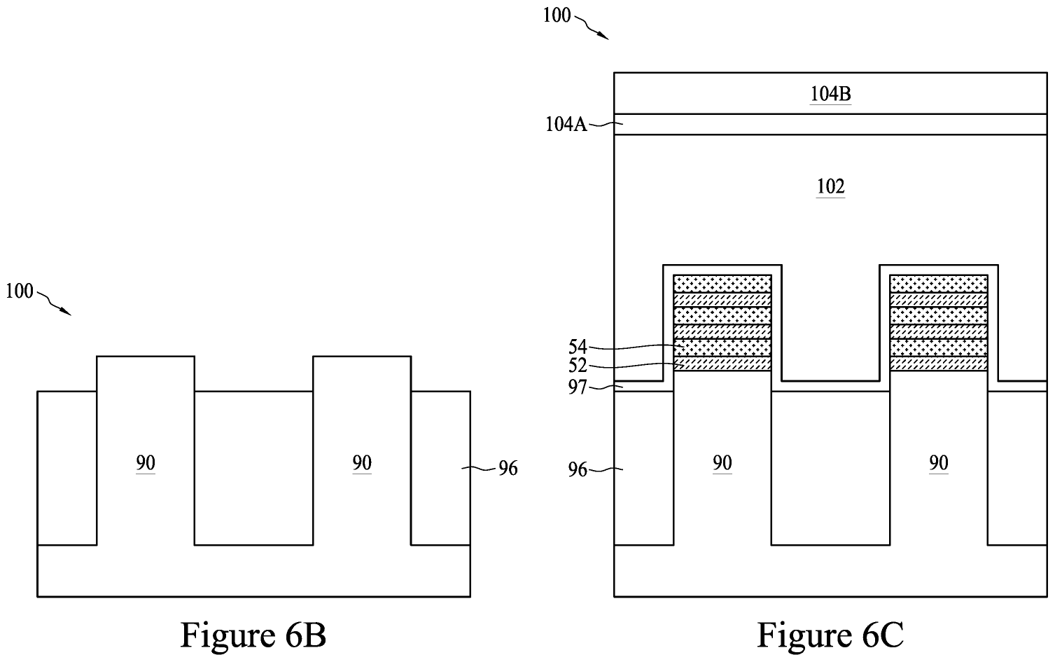

Next, in FIGS. 6A-6C, the gate spacer layers 108 are etched by an anisotropic etching process to form gate spacers 108. The anisotropic etching process may remove horizontal portions of the gate spacer layer 108 (e.g., portions over the STI regions 96 and the dummy gates 102), with remaining vertical portions of the gate spacer layer 108 (e.g., portions along sidewalls of the dummy gates 102 and the dummy gate dielectric 97) forming the gate spacers 108.

After the formation of the gate spacers 108, implantation for lightly doped source/drain (LDD) regions (not shown) may be performed. Appropriate type (e.g., p-type or n-type) impurities may be implanted into the exposed layer stacks 92 and/or semiconductor fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities of from about 10¹⁵ cm⁻³ to about 10¹⁶ cm⁻³. An anneal process may be used to activate the implanted impurities.

Next, openings 110 (which may also be referred to as recesses) are formed in the layer stacks 92. The openings 110 may extend through the layer stacks 92 and into the fins 90. The openings 110 may be formed by an anisotropic etching process using, e.g., the dummy gates 102 and the gate spacers 108 as an etching mask.

After the openings 110 are formed, a selective etching process is performed to recess end portions of the first semiconductor material 52 exposed by the openings 110 without substantially attacking the second semiconductor material 54. After the selective etching process, recesses (also referred to as sidewall recesses) are formed in the first semiconductor material 52 at locations where the removed end portions used to be.

Next, an inner spacer layer is formed (e.g., conformally) in the openings 110. The inner spacer layer also fills the sidewall recesses of the first semiconductor material 52 formed by the previous selective etching process. The inner spacer layer may be a suitable dielectric material, such as silicon carbonitride (SiCN), silicon oxycarbonitride (SiOCN), or the like, formed by a suitable deposition method such as PVD, CVD, atomic layer deposition (ALD), or the like. Next, an etching process, such as an anisotropic etching process, is performed to remove portions of the inner spacer layers disposed outside the sidewall recesses of the first semiconductor material 52. The remaining portions of the inner spacer layers (e.g., portions disposed inside the sidewall recesses of the first semiconductor material 52) form inner spacers 55. As illustrated in FIG. 6A, the openings 110 expose sidewalls of the second semiconductor material 54 and expose an upper surface 90U of the fin 90.

FIGS. 6B and 6C illustrate cross-sectional views of the NSFET device 100 in FIG. 6A along cross-sections E-E and F-F, respectively. In FIG. 6B, the portions of the gate spacer layer 108 disposed on the upper surface of the STI regions 96 between neighboring fins 90 are completely removed by the anisotropic etching process used for forming the gate spacers 108. In some embodiments, portions of the gate spacer layer 108 are left (e.g., remain) between neighboring fins 90 on the upper surface of the STI regions 96. Those portions of the gate spacer layer 108 may be left because the anisotropic etching process discussed above may not completely remove the gate spacer layer 108 disposed between neighboring fins 90, due to the small distance between the neighboring fins 90 reducing efficiency of the anisotropic etching process.

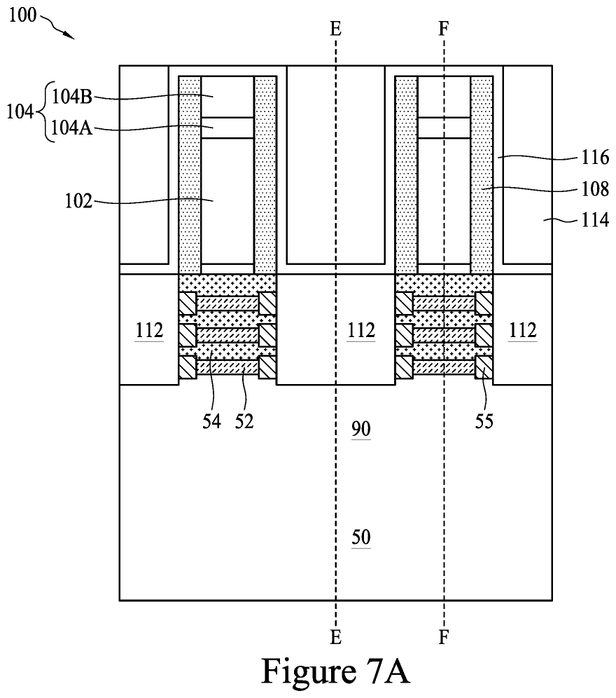

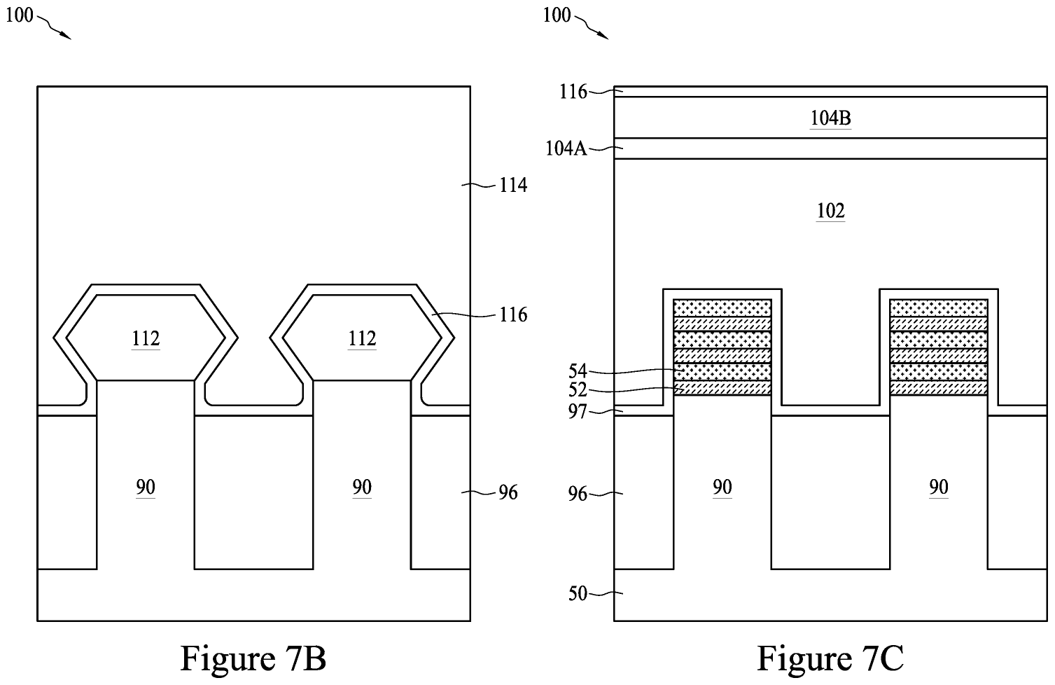

Next, in FIGS. 7A-7C, source/drain regions 112 are formed in the openings 110. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed gates of the resulting NSFET device.

The epitaxial source/drain regions 112 are epitaxially grown in the openings 110. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with dopants to form source/drain regions, similar to the process previously discussed for forming lightly-doped source/drain regions, followed by an anneal. The source/drain regions may have an impurity concentration of between about 10¹⁹ cm⁻³ and about 10²¹ cm⁻³. The n-type and/or p-type impurities for source/drain regions may be any of the impurities previously discussed. In some embodiments, the epitaxial source/drain regions 112 may be in situ doped during growth.

As a result of the epitaxy processes used to form the epitaxial source/drain regions 112, upper surfaces of the epitaxial source/drain regions 112 have facets which expand laterally outward beyond sidewalls of the fins 90. In the illustrated embodiment, adjacent epitaxial source/drain regions 112 remain separated (see FIG. 7B) after the epitaxy process is completed. In other embodiments, these facets cause adjacent epitaxial source/drain regions 112 of a same NSFET to merge.

Next, a contact etch stop layer (CESL) 116 is formed (e.g., conformally) over the source/drain regions 112 and over the dummy gate 102, and a first inter-layer dielectric (ILD) 114 is then deposited over the CESL 116. The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, plasma-enhanced CVD (PECVD), or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may be used. FIGS. 7B and 7C illustrate cross-sectional views of the NSFET device 100 of FIG. 7A, but along cross-section E-E and F-F in FIG. 7A, respectively.

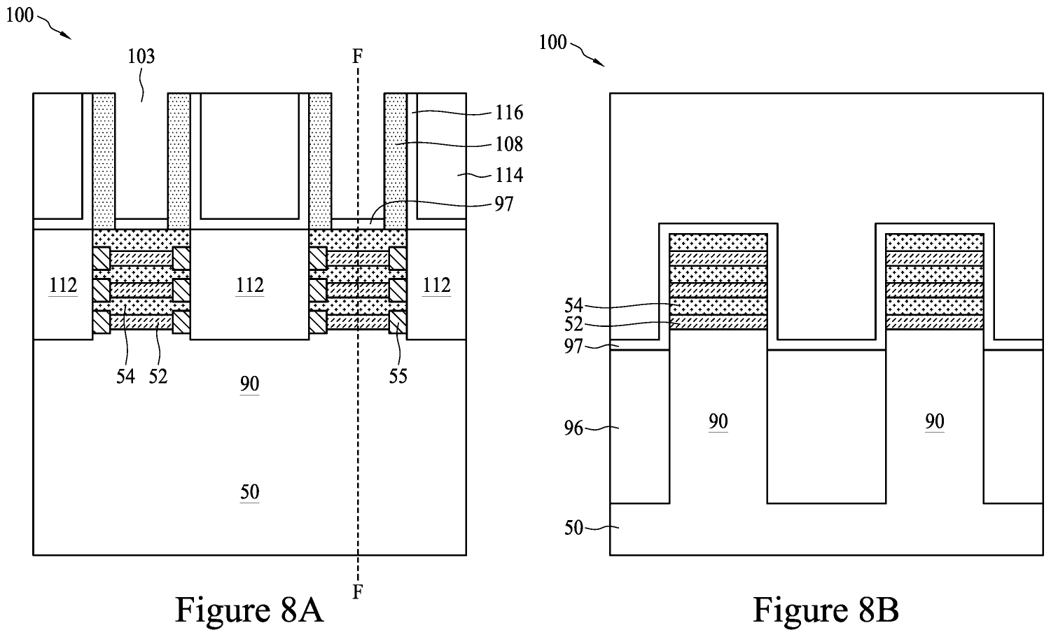

Next, in FIGS. 8A and 8B, the dummy gates 102 are removed. To remove the dummy gates 102, a planarization process, such as a CMP, is performed to level the top surfaces of the first ILD 114 and CESL 116 with the top surfaces of the dummy gates 102 and gate spacers 108. The planarization process may also remove the masks 104 (see FIG. 7A) on the dummy gates 102, and portions of the gate spacers 108 along sidewalls of the masks 104. After the planarization process, top surfaces of the dummy gates 102, gate spacers 108, CESL 116, and first ILD 114 are level. Accordingly, the top surfaces of the dummy gates 102 are exposed through the first ILD 114.

Next, the dummy gates 102 are removed in an etching step(s), so that recesses 103 are formed. In some embodiments, the dummy gates 102 are removed by an anisotropic dry etch process. For example, the etching process may include a dry etch process using reaction gas(es) that selectively etch the dummy gates 102 without etching the first ILD 114 or the gate spacers 108. During the removal of the dummy gates 102, the dummy gate dielectric 97 may be used as an etch stop layer when the dummy gates 102 are etched. The dummy gate dielectric 97 may then be removed after the removal of the dummy gates 102. FIG. 8B illustrates the cross-sectional view of the NSFET device 100 of FIG. 8A along the cross-section F-F.

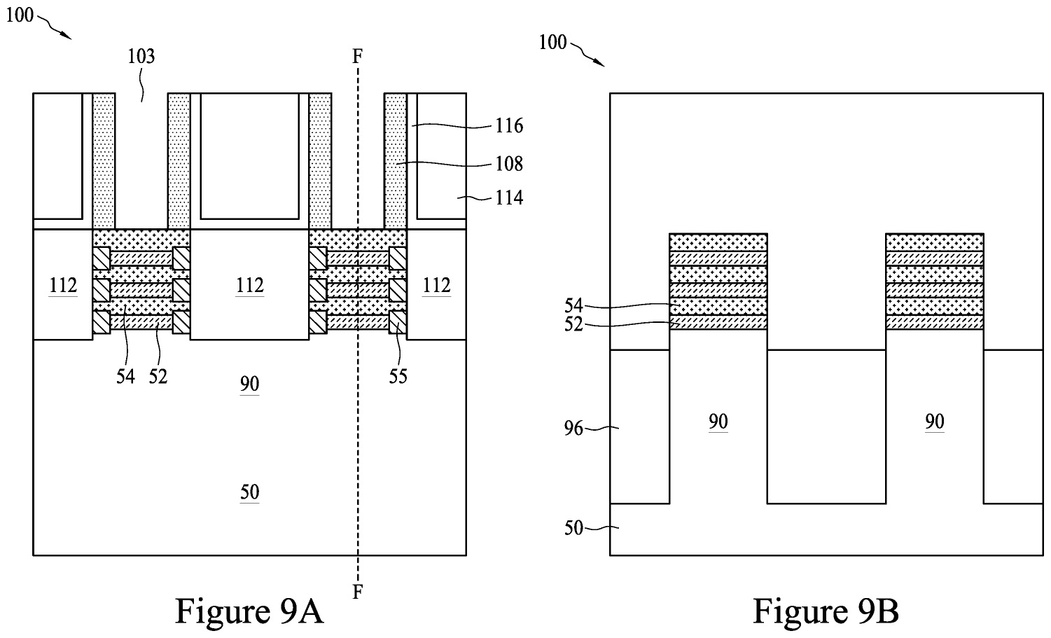

Next, in FIGS. 9A and 9B, the dummy gate dielectric 97 in the recesses 103 is removed. An etching process, such as an isotropic etching process, may be performed to remove the dummy gate dielectric 97. In an embodiment, an isotropic etching process using an etching gas that comprises HF and NH₃ is performed to remove the dummy gate dielectric 97. As illustrated in FIGS. 9A and 9B, each recess 103 exposes a channel region of the NSFET. Each channel region is disposed between neighboring pairs of the epitaxial source/drain regions 112.

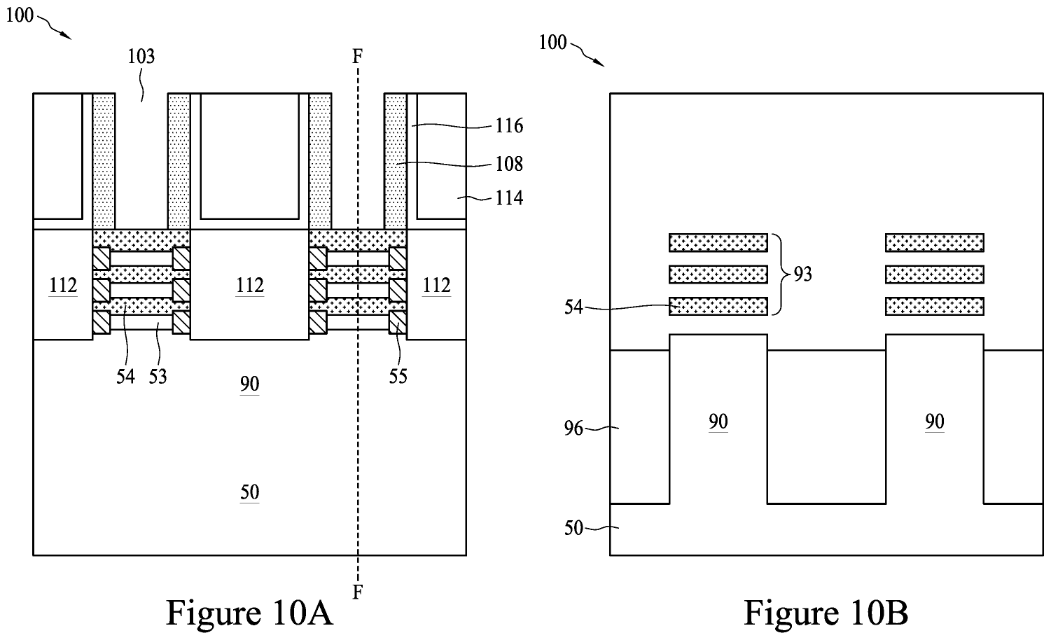

Next, in FIGS. 10A and 10B, the first semiconductor material 52 (e.g., portions exposed by the recesses 103) is removed to release the second semiconductor material 54. After the first semiconductor material 52 is removed, the second semiconductor material 54 (e.g., portions underlying the dummy gates 102 before the dummy gates 102 are removed) forms a plurality of nanostructures 54 that extend horizontally (e.g., parallel to a major upper surface of the substrate 50). The nanostructures 54 may be collectively referred to as the channel regions 93 or the channel layers 93 of the NSFET device 100 formed. As illustrated in FIG. 10A, gaps 53 (e.g., empty spaces) are formed between the nanostructures 54 by the removal of the first semiconductor material 52. In some embodiments, the nanostructures 54 are nanosheets or nanowires, depending on, e.g., the dimensions (e.g., size and/or aspect ratio) of the nanostructures 54.

In some embodiments, the first semiconductor material 52 is removed by a selective etching process using an etchant that is selective to (e.g., having a higher etch rate for) the first semiconductor material 52, such that the first semiconductor material 52 is removed without substantially attacking the second semiconductor material 54. In some embodiments, an isotropic etching process is performed to remove the first semiconductor material 52. The isotropic etching process is performed using an etching gas, and optionally, a carrier gas, where the etching gas comprises F₂ and HF, and the carrier gas may be an inert gas such as Ar, He, N₂, combinations thereof, or the like, in some embodiments.

FIG. 10A illustrates the cross-sectional view of the NSFET device 100 along a longitudinal axis of the fin (e.g., along a current flow direction in the fin), and FIG. 10B illustrates the cross-sectional view of the NSFET device 100 along cross-section F-F, which is a cross-section along a direction perpendicular to the longitudinal axis of the fin and across a middle portion of the nanostructure 54.

As illustrated in FIG. 10A, each of the nanostructures 54 has a rectangular shaped cross-section along the longitudinal axis of the fin. Similarly, in FIG. 10B, in a cross-section along a direction perpendicular to the longitudinal axis of the fin and across a middle portion of the nanostructure 54, each of the nanostructures 54 has a rectangular shaped cross-section.

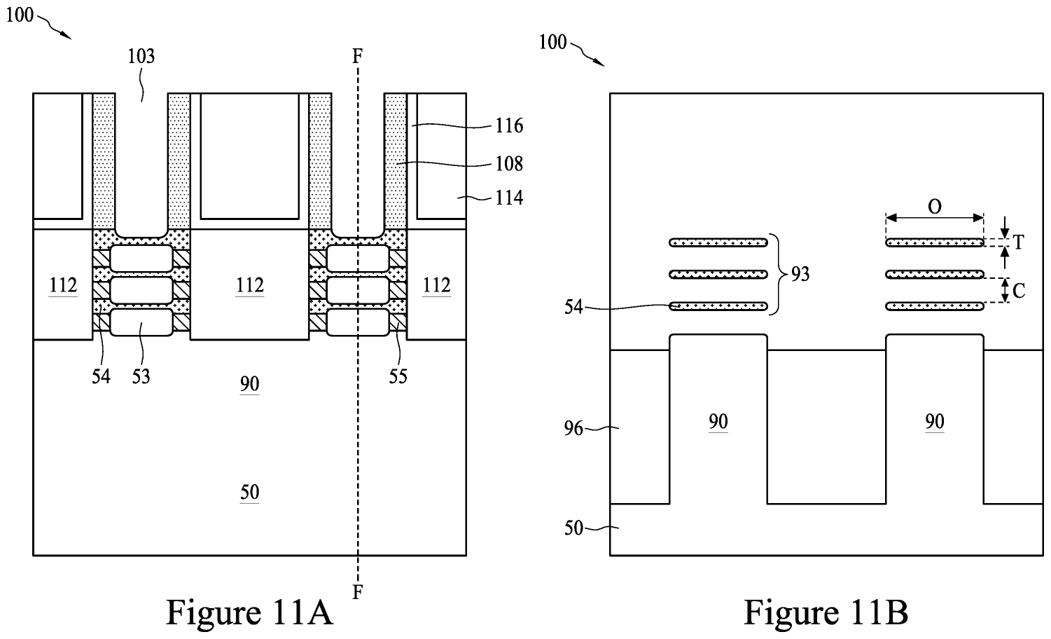

Next, in FIGS. 11A and 11B, the nanostructures 54 are reshaped by a nanostructure reshaping process (e.g., an isotropic etching process). In some embodiments, the nanostructures 54 are reshaped by a selective etching process using an etchant that is selective to the material of the nanostructures 54 (e.g., the second semiconductor material 54), such that the nanostructures 54 are etched without substantially attacking other materials in the NSFET device 100, such as oxide, silicon nitride, and low-K dielectric materials.

In some embodiments, the isotropic etching process (e.g., a selective etching process) to reshape the nanostructures 54 is performed using an etching gas, and optionally, a carrier gas, where the etching gas comprises F₂ and NH₃, and the carrier gas may be an inert gas such as Ar, He, N₂, combinations thereof, or the like.

Besides using a mixture of F₂ and NH₃ as the etching gas, other suitable etching gases, such as ClF₃, or a mixture of NF₃ and NH₃, may alternatively be used as the etching gas to reshape the nanostructures 54. For example, an isotropic etching process (e.g., an isotropic plasma etching process) using an etching gas comprising NF₃ and NH₃ may be performed to reshape the nanostructures 54.

The nanostructure reshaping process thins the middle portion of each nanostructure 54 while the end portions of the nanostructure 54 remain substantially unchanged, thus generating a dumbbell shaped cross-section for the nanostructure 54 in FIG. 11A. In addition, the nanostructure re-shaping process removes the sharp edges (e.g., see the 90-degree edges of the nanostructures 54 in FIG. 10B) of the nanostructures 54, thus generating rounded edges for each nanostructure 54 (see the rounded corners of each nanostructure 54 in FIG. 11B), as described in more details below.

As illustrated in FIG. 11A, after the nanostructure reshaping process, in the cross-section along the longitudinal axis of the fin, each of the nanostructures 54 has a dumbbell shape, where end portions of the nanostructure 54 (e.g., portions physically contacting the source/drain regions 112) have a thickness (measured along the vertical direction of FIG. 11A) larger than that of the middle portion (e.g., a portion mid-way between the end portions). In some embodiments, a difference between the thicknesses of the end portion of the nanostructure 54 and the middle portion of the nanostructure 54 is between about 0 nm and about 3 nm. In the example of FIG. 11A, the upper surface and the lower surface of the middle portion of each nanostructure 54 are illustrated as level surfaces (e.g., flat surfaces). This is, of course, merely a non-limiting example. In some embodiments, the upper surface and lower surface of the middle portion of each nanostructure 54 are curved, such as curved toward a horizontal center axis of the nanostructure 54. In addition, in the cross-section of FIG. 11B, each of the nanostructures 54 has a stadium shape (may also be referred to as a racetrack shape, a discorectangle shape, an obround shape, or a sausage body shape). In particular, in the cross-section of FIG. 11B, the corners of each nanostructure 54 are rounded (e.g., curved). In some embodiments, a thickness T (also referred to as sheet thickness) of the nanostructure 54 (e.g., nanosheet) is between about 6.3 nm and about 8.2 nm, with a mean value (e.g., average value) of about 7.1 nm. A spacing C (also referred to as sheet-to-sheet distance) between adjacent nanostructures 54 is between about 4.5 nm and about 5.9 nm, with a mean value of about 5.2 nm, in some embodiments. A width O (also referred to as sheet width) of the nanostructure 54 is between about 94.9 nm and about 97.5 nm, with a mean value of about 96.2 nm, in some embodiments.

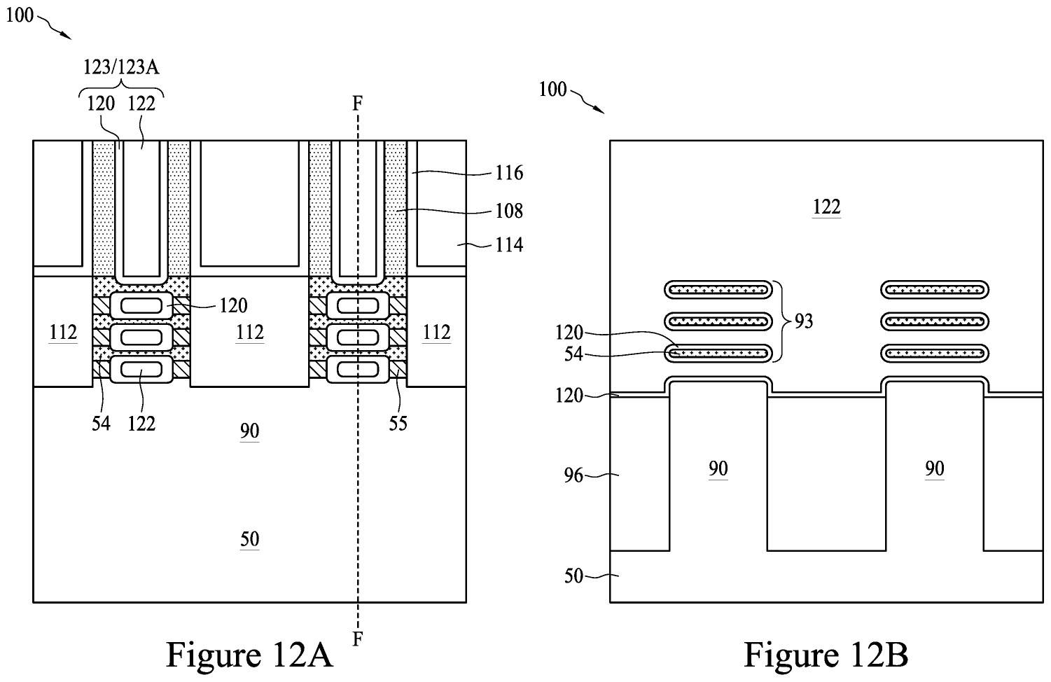

As feature sizes continue to shrink in advanced processing nodes, the distance between adjacent nanostructures 54 may become so small that it may be difficult to form layers (e.g., gate dielectric layer, work function layers) around the nanostructures 54 in subsequent processing. By reshaping the nanostructures 54, e.g., thinning the middle portions of the nanostructures 54, the distance between adjacent nanostructures 54 is increased, thus making it easier to form, e.g., gate dielectric layer 120 (see FIGS. 12A and 12B) around the nanostructures 54. In addition, since the thickness T of the nanostructures 54, which form the channel regions 93 of the NSFET device 100, is reduced by the nanostructure reshaping process, it is easier to control (e.g., turning on or off) the NSFET device 100 by applying a gate control voltage on the metal gate formed in subsequent processing.

In some embodiments, the nanostructure reshaping process illustrated in FIGS. 11A and 11B is omitted. In subsequent figures, the channel regions 93 of the NSFET device 100 are illustrated as having the cross-sections of FIGS. 11A and 11B, with the understanding that the channel regions 93 may have the cross-sections of FIGS. 10A and 10B (e.g., when the nanostructure reshaping process is omitted).

Next, in FIGS. 12A and 12B, gate dielectric layers 120 and gate electrodes 122 are formed to form replacement gates. The gate dielectric layers 120 are deposited conformally in the recesses 103, such as on the top surfaces and the sidewalls of the semiconductor fin 90, and on sidewalls of the gate spacers 108. The gate dielectric layers 120 may also be formed on the top surface of the first ILD 114. Notably, the gate dielectric layers 120 are formed to wrap around the nanostructures 54. In accordance with some embodiments, the gate dielectric layers 120 comprise silicon oxide, silicon nitride, or multilayers thereof. In some embodiments, the gate dielectric layers 120 are formed of a high-k dielectric material, and in these embodiments, the gate dielectric layers 120 may have a k value greater than about 7.0, and may include a metal oxide or a silicate of Hf, Al, Zr, La, Mg, Ba, Ti, or Pb, or combinations thereof. The formation methods of the gate dielectric layers 120 may include Molecular-Beam Deposition (MBD), ALD, PECVD, and the like.

Next, the gate electrodes 122 are deposited over and around the gate dielectric layers 120, and fill the remaining portions of the recesses 103. The gate electrodes 122 may include a metal-containing material such as TiN, TiO, TaN, TaC, Co, Ru, Al, W, combinations thereof, or multi-layers thereof. For example, although a single layer gate electrode 122 is illustrated, the gate electrode 122 may comprise any number of liner layers (e.g., barrier layers), any number of work function tuning layers, and a fill material. After the filling of the gate electrodes 122, a planarization process, such as a CMP, may be performed to remove the excess portions of the gate dielectric layers 120 and the material of the gate electrodes 122, which excess portions are over the top surface of the first ILD 114. The remaining portions of material of the gate electrodes 122 and the gate dielectric layers 120 thus form replacement gates of the resulting NSFET device 100. Each gate electrode 122 and the corresponding gate dielectric layer 120 may be collectively referred to as a gate stack 123, a replacement gate structure 123, a metal gate structure 123, or a gate structure 123. Each gate structure 123 extends around the respective nanostructures 54.

Next, the formation process proceeds to the cutting of gate structures 123 and the cutting (e.g., removing) of some nanostructures 54 in order to form isolated transistors. The cutting of gate structure 123 is referred to as a Cut Metal Gate (CMG) process. The cutting of nanostructures 54 (and portions of their respective underlying fins 90) is referred to as a Continuous Metal On-Diffusion Edge (CMODE) process, or sometimes referred to as a Cut Metal on-Diffusion Edge (CMODE) process. Note that in the illustrated CMODE process, the cutting of nanostructures 54 and their respective underlying fins 90 is performed after the formation of replacement gate stacks 123. In the illustrated CMG process and CMODE process, some examples of the cutting positions are illustrated, as shown in FIGS. 13C and 19C. It is appreciated that the cutting processes may be performed at different positions and with different sizes, depending on the design of the transistors.

In FIGS. 12A and 12B, two fins 90 and two gate structures 123 are illustrated. This is, of course, a non-limiting example. The number of fins 90 and the number of gate structures 123 in the NSFET device 100 may be any suitable number. In subsequent figures (e.g., FIGS. 13A-19C), to facilitate discussion of the CMG process and CMODE process, three fins 90 (which are labeled as 90A, 90B, and 90C) and four gate structures 123 (which are labeled as 123A, 123B, 123C, and 123D) are illustrated.

Referring next to FIGS. 13A-13C, dielectric plugs 125 are formed to cut the gate structure 123B into a plurality of separate segments. FIG. 13C shows the top view (e.g., a plan view) of the NSFET device 100 after the dielectric plugs 125 are formed. For simplicity, not all features of the NSFET device 100 are illustrated in FIG. 13C. For example, FIG. 13C only shows the fins 90A, 90B, 90C (may be collectively referred to as fins 90), the gate structures 123A, 123B, 123C, and 123D (may be collectively referred to as gate structures 123), gate spacers 108 around the sidewalls of the gate structures 123, and the dielectric plugs 125.

In some embodiments, the dielectric plugs 125 are formed by forming openings in the gate structure 123B and the first ILD 114 (e.g., using photo lithography and etching techniques), and filling the openings with a dielectric material, such as silicon nitride, silicon oxide, combinations thereof, or the like. Next, a planarization process, such as CMP, may be performed to remove excess portions of the dielectric material from the upper surface of the first ILD 114, and the remaining portions of the dielectric material in the openings form the dielectric plugs 125.

In the illustrated example, the dielectric plugs 125 are formed on opposing sides of the fin 90B. For example, in FIG. 13C, one of the dielectric plugs 125 is formed between the fins 90A and 90B, and another one the dielectric plugs 125 is formed between the fins 90B and 90C. A dimension W1 of the dielectric plug 125, measured along the direction of cross-section B-B, is larger than a dimension W2 of the gate structure 123B to ensure that the dielectric plug 125 cuts the gate structure 123B into separate segments that are electrically isolated from each other, in the illustrated embodiment. As shown in FIG. 13B, the dielectric plugs 125 extend through the gate structure 123 and into the STI regions 96 to ensure separation of the different segments of the gate structure 123B. Note that the dielectric plugs 125 are not in the cross-section B-B of FIG. 13C, thus are not visible in FIG. 13A.

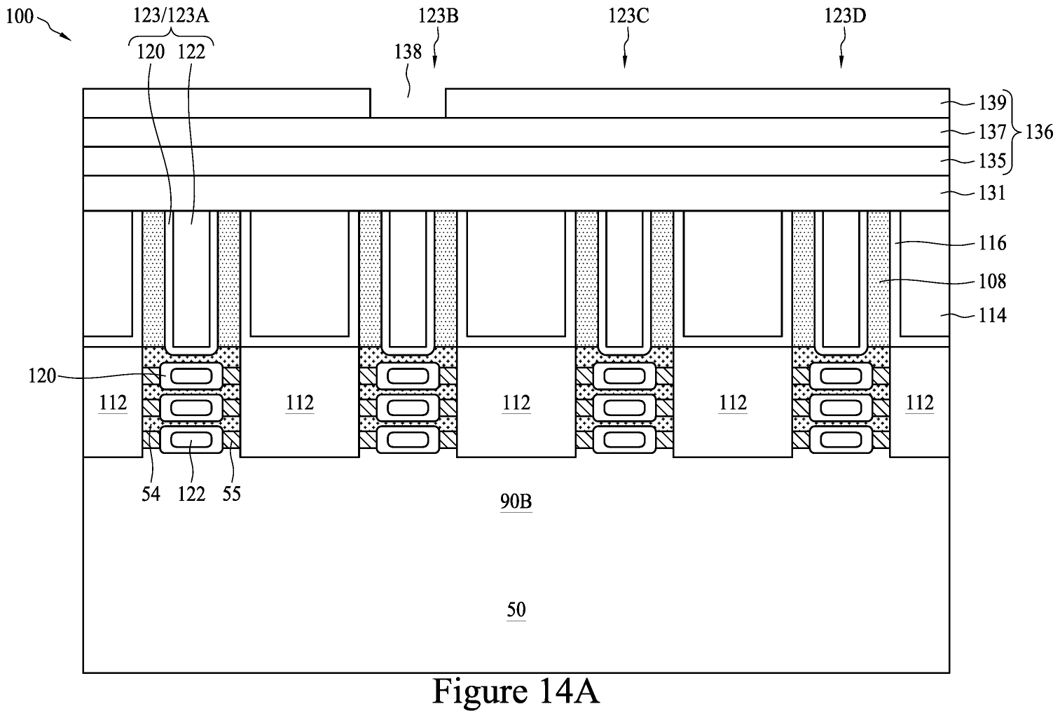

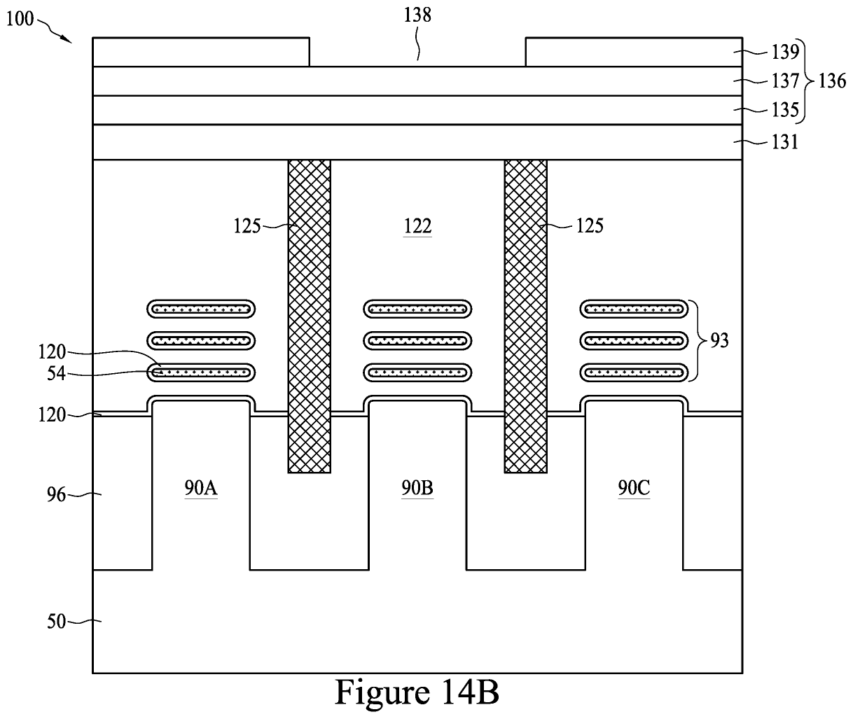

Next, in FIGS. 14A and 14B, a hard mask layer 131 is formed over the first ILD 114 and the gate structures 123. The hard mask layer 131 may be a single-layer hard mask formed of, e.g., silicon nitride, silicon oxynitride, or the like, using a suitable formation method such as CVD. In some embodiments, the hard mask layer 131 has a multi-layered structure. For example, the hard mask layers 131 may include a silicon layer sandwiched between two silicon nitride layers.

Next, an etching mask 136 is formed over the hard mask layer 131. The etching mask 136 may have a single-layered structure (which may include a photoresist layer), or a dual-layered structure including a Bottom Anti-reflective Coating (BARC) layer and a photoresist layer. In the example of FIGS. 14A and 14B, the etching mask 136 has a tri-layered structure, which includes a bottom layer 135 (e.g., a BARC layer), a middle layer 137 (e.g., a silicon nitride layer, or a silicon oxynitride layer), and a top layer 139 (e.g., a photoresist layer).

Next, an opening 138 is formed in the top layer 139 of the etching mask 136. Next, the pattern of the top layer 139 is extended through the middle layer 137 and the bottom layer 135, and is transferred to the hard mask layer 131, using a suitable method, such as one or more anisotropic etching processes. Next, the etching mask 136 is removed by a suitable process, such as etching, grinding, combinations thereof, or the like.

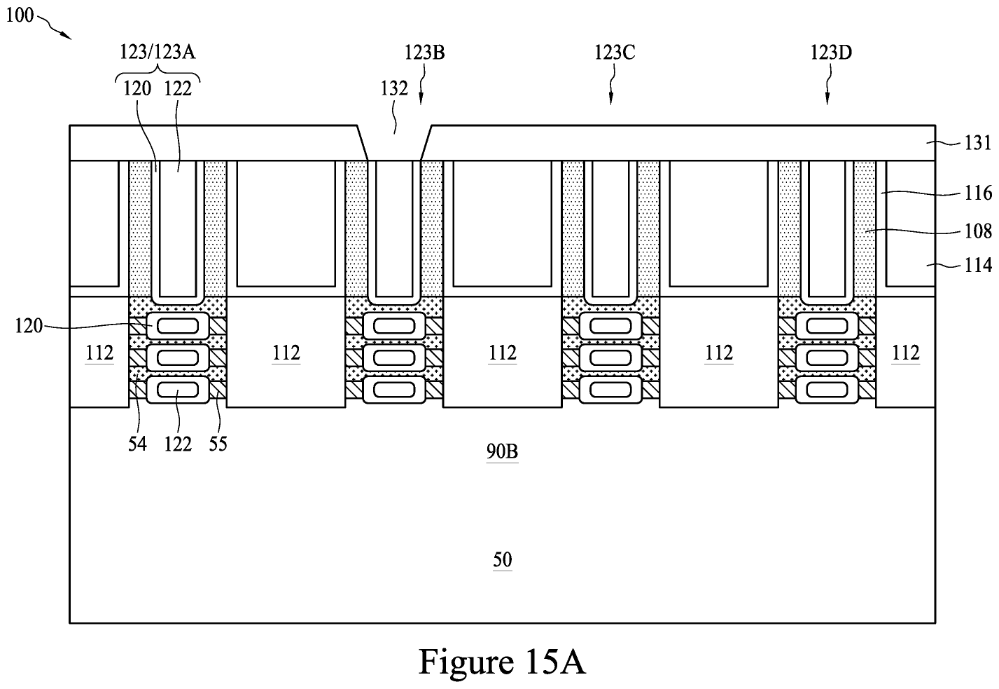

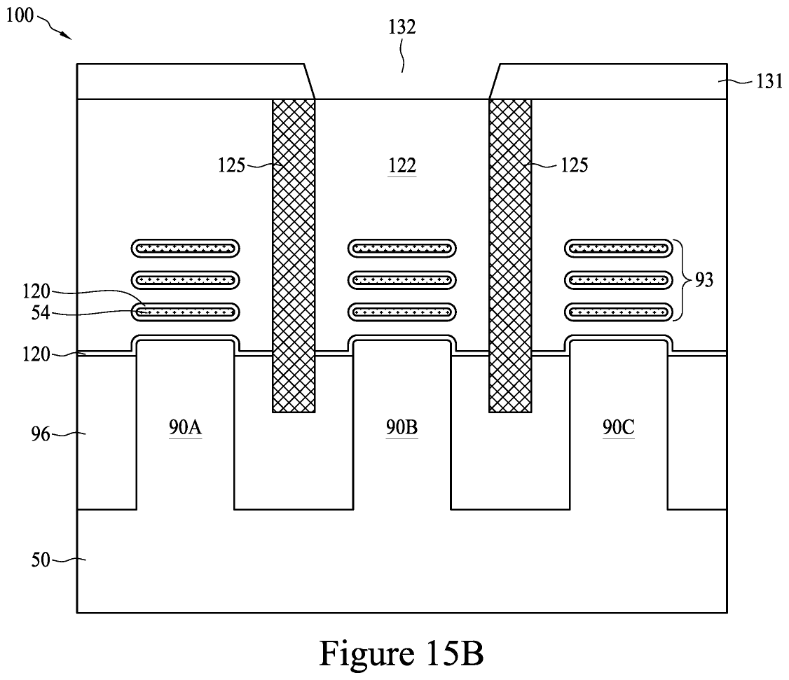

FIGS. 15A and 15B show the NSFET device 100 after the removal of the etching mask 136. As illustrated in FIGS. 15A and 15B, the opening 138 is transferred to the hard mask layer 131 as an opening 132 in the hard mask layer. The opening 132 exposes a segment of the gate structure 123B disposed between the dielectric plugs 125, so that the exposed segment can be removed and replaced by an isolation structure in subsequent processing, details of which are discussed hereinafter. In a top view, the location of the opening 132 is substantially the same as the subsequently formed isolation structure 141 (see FIG. 19C).

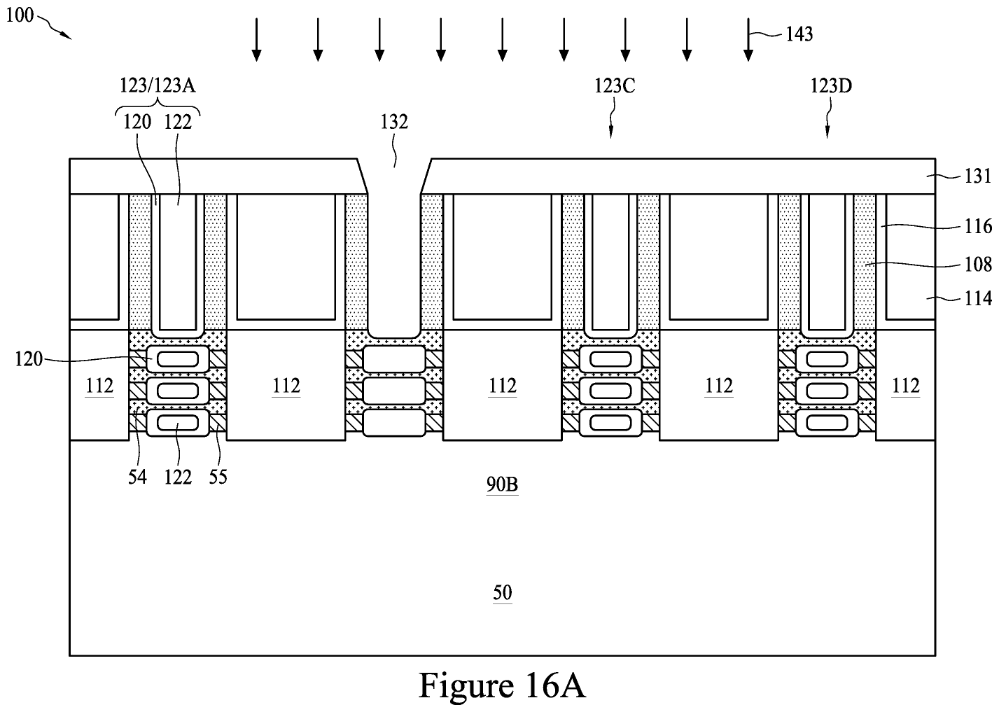

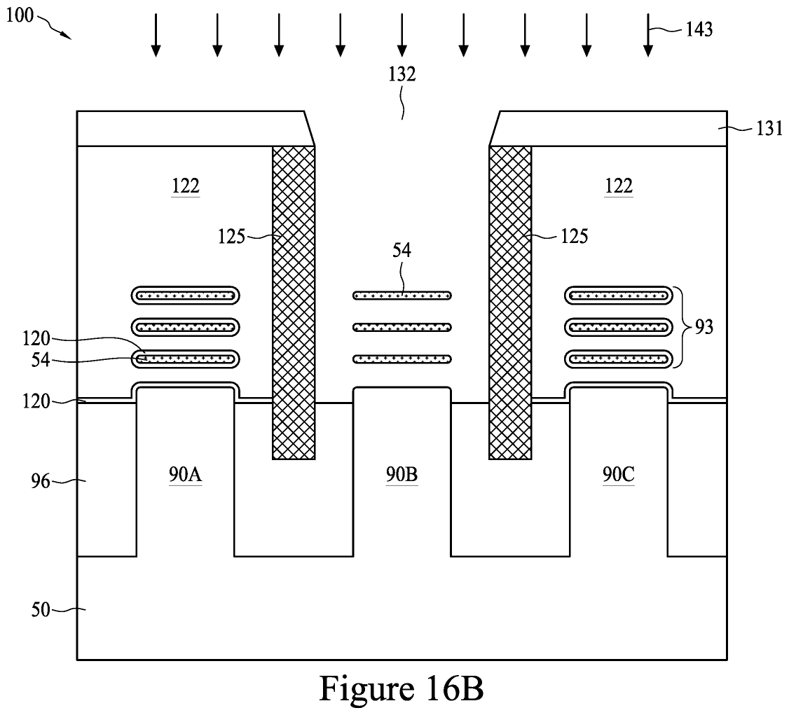

Next, in FIGS. 16A and 16B, an etching process is performed to remove the exposed segment of the gate structure 123B. In some embodiments, the etching process is a wet etching process performed using a strong etching chemical (e.g., an etching fluid), such as the piranha solution (e.g., a mixture of sulfuric acid and hydrogen peroxide), to selectively remove the exposed segment of the gate structure 123B without substantially attacking other layers/materials of the NSFET device 100. The hard mask layer 131, the gate spacers 108, and the dielectric plugs 125 may help to protect (e.g., shield) other areas of the NSFET device 100 from the wet etching process, and limit the effect of the wet etching process to the area defined by the opening 132. After the wet etching process, the gate electrode 122 and the gate dielectric layer 120 in the exposed segment of the gate structure 123B are removed (e.g., completely removed), and the opening 132 is extended downward through the gate structure 123B to expose the upper surface of the STI regions 96. The nanostructures 54 previously surrounded by the exposed segment of the gate structure 123B are now exposed to the opening 132.

Next, an anisotropic etching process 143 is performed to remove the nanostructures 54 in the opening 132. In some embodiments, the anisotropic etching process 143 is a plasma dry etching process, and therefore, may be referred to as a plasma dry etching process 143 hereinafter. The plasma dry etching process 143 may be performed using a gas source comprising HBr, Cl₂, or combinations thereof. In some embodiments, during the plasma dry etching processing 143, other gases, such as O₂, CO₂, or a combination thereof, may be added to the gas source to adjust various aspects of the plasma dry etching process, such as etching rate, etching selectivity, and/or etching profile.

During the plasma dry etching process 143, the gas source is ignited into plasma by a plasma etching tool. The plasma etching tools may use an Inductively Coupled Plasma (ICP)/dipole antenna. In some embodiments, an RF power generator of the plasma etching tool generates an RF power source (e.g., an RF signal) at 13.56 MHz or 27 MHz. The plasma etching tool chamber may be operated at a pressure between about 3 mTorr and about 150 mTorr, and at a temperature between about 20 degrees Celsius and about 150 degrees Celsius. A power of the RF power source may be between about 100 W and about 2500 W. In some embodiments, the plasma dry etching process uses pulsed plasma etch, where a duty cycle of the RF power source is in a range between about 20% to 100%. In some embodiments, an RF bias power to the pedestal of the plasma etching tool between about 10 W and about 1200 W is used for the plasma dry etching process.

In some embodiments, in order to protect the hard mask layer 131 and to preserve the dimension of the opening 132 during the plasma dry etching process 143, a passivation layer is formed (e.g., conformally) over the upper surface of the hard mask layer 131 and along the sidewalls and the bottom of the opening 132. The passivation layer may also be formed over surfaces of the nanostructures 54. The passivation layer may be a carbon-based passivation layer formed by injecting CH₄ into the plasma etching tool during the plasma dry etching process. A carrier gas, such as Ar or N₂, may be used to carrier CH₄ into the plasma etching tool. In some embodiments, the passivation layer is a SiO-based passivation layer formed by injecting SiCl₄ and O₂ gases (e.g., simultaneously or sequentially) into the plasma etching tool during the plasma dry etching process. A carrier gas, such as Ar or N₂, may be used to carrier SiCl₄ and O₂ into the plasma etching tool. The SiO-based passivation layer may be formed by the chemical reaction:

SiCl₄+O₂->SiO₂+Cl₂

In some embodiments, addition chemical(s), such as HBr, is injected into the plasma etching tool chamber along with SiCl₄ to facilitate the dissociation of SiCl₄ in the SiO-based passivation layer formation process. Chemical reactions, such as

SiCl₄+HBr->SiCl₃+HCl+Br

may happen to speed up the dissociation of SiCl₄ and the formation of SiO-based passivation layer. The bromine (Br) generated by the above chemical reaction may further react with SiO₂ to form SiBrO. Therefore, the composition of the SiO-based passivation layer may include SiBrO.

After the passivation layer is formed, a break-through etching step is performed to remove the passivation layer from the etch front (e.g., remove the passivation layer from the surfaces of the nanostructures 54 and from the bottom of the opening 132), such that the plasma dry etching process 143 can be performed next to remove the nanostructures 54. In some embodiments, the break-through etching step is an anisotropic etching process (e.g., a plasma etching process) performed using a gas source comprising CF₄, CHF₃, C₄F₆, or combinations thereof. After the break-through etching step, the passivation layer at the bottom of the opening 132 is removed, while the sidewalls of the opening 132 remain covered by the passivation layer.

In some embodiments, the etching process to remove the nanostructures 54 underlying the opening 132 includes multiple etching cycles, where each of the multiple etching cycles include the following three sequential processing steps: 1) forming the passivation layer (e.g., carbon-based or SiO-based passivation layer) on the hard mask layer 131 and along the sidewalls and the bottom of the opening 132; 2) performing the break-through etching step to remove the passivation layer from the etch front; and 3) performing the plasma dry etching process 143 to remove the nanostructures 54.

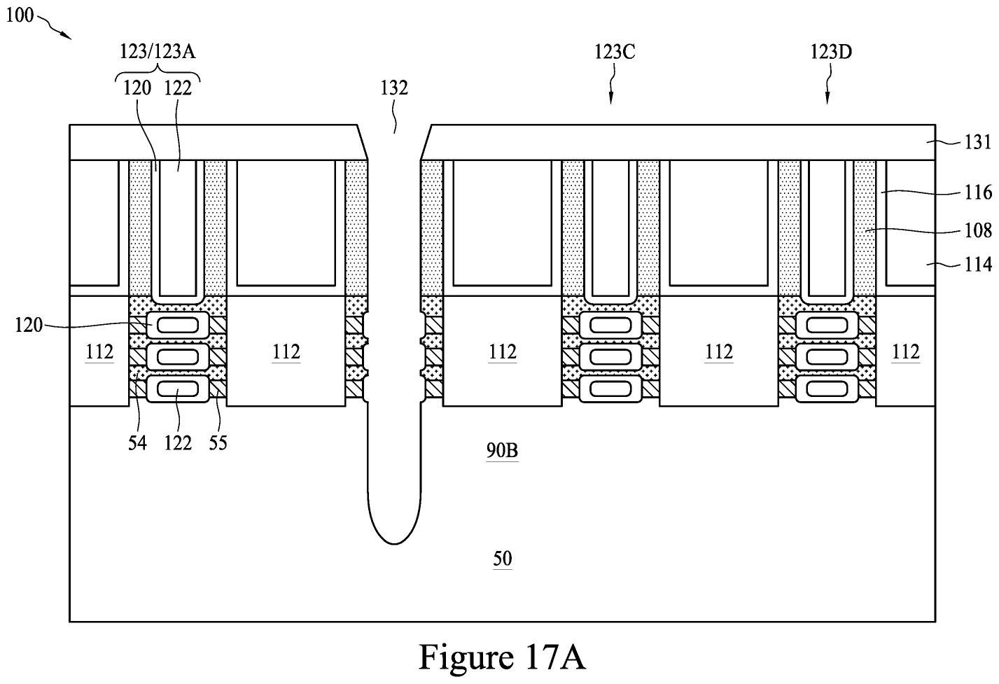

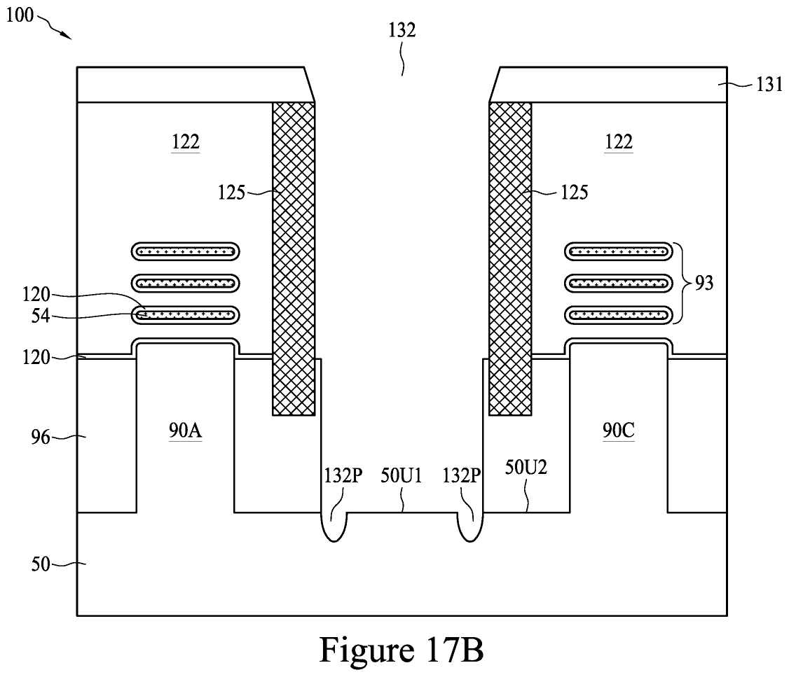

FIGS. 17A and 17B illustrate the NSFET device 100 after the nanostructures 54 are removed. As illustrated in FIGS. 17A and 17B, the segment of gate structure 123B exposed by the opening 132 is completely removed. In addition, the fin 90B and portions of the STI regions 96 under the openings 132 are also removed. Therefore, as shown in FIG. 17B, the opening 132 extends through the STI region 96 and into the substrate 50. As a result, an upper surface 50U1 of the portions of the substrate 50 underlying the opening 132 is lower (e.g., more recessed) than an upper surface 50U2 of other (un-etched) portions of the substrate 50. Notably, in FIG. 17B, the opening 132 includes two protrusion portions 132P (also referred to as protrusions 132P, or notches 132P) at the bottom corners of the opening 132. In particular, the protrusion portions 132P extend below the upper surface 50U1 of the substrate 50 in FIG. 17B. A width of the protrusions 132P, measured along the horizontal direction of FIG. 17B, may be about 20 nm, as an example. The protrusions 132P may be formed due to faster etching rate achieved by the plasma dry etching process 143 at or along the edges of the nanostructures 54.

As illustrated in FIGS. 17A and 17B, after removal of the nanostructures 54, the opening 132 (may also be referred to as a recess 132) exposes sidewalls of the dielectric plugs 125 facing the nanostructures 54, and exposes inner sidewalls of the gate spacers 108 facing the opening 132. In other words, in a top view, the opening 132 is defined by opposing sidewalls of the dielectric plugs 125 along a first direction (e.g., along the direction of cross-section A-A), and is defined by opposing sidewalls of the gate spacers 108 along a second direction (e.g., along the direction of cross-section B-B). Since the opening 132 is subsequently filled with a dielectric material to form the isolation structure 141, the location of the isolation structure 141 in the top view of FIG. 19C also illustrates the location of the opening 132 before it was filled.

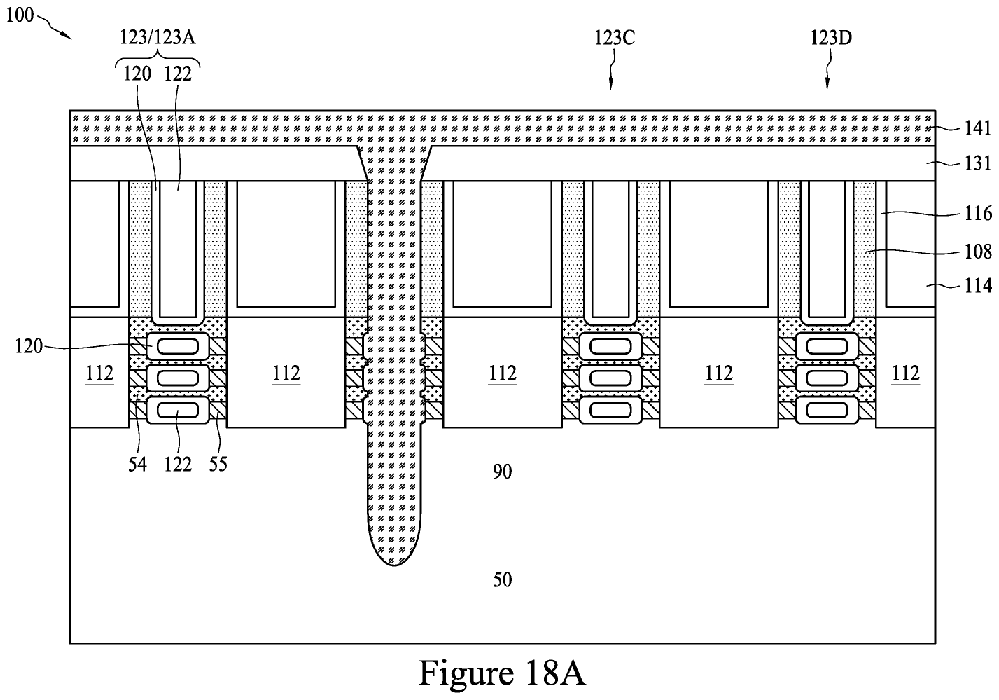

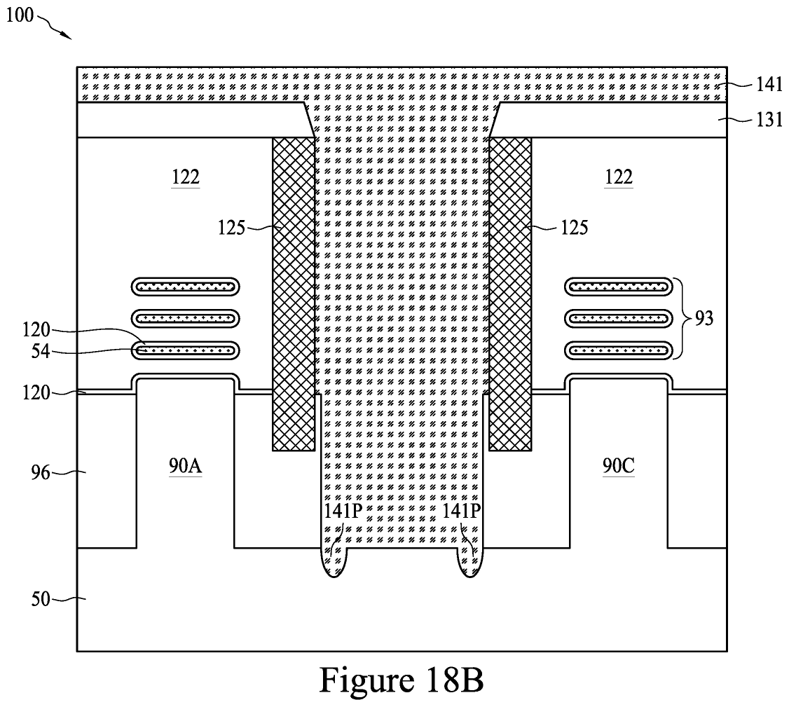

Next, in FIGS. 18A and 18B, a dielectric material 141 is formed over the hard mask layer 131 and to fill the opening 132. The dielectric material 141 may be, e.g., silicon oxide, silicon nitride, silicon oxynitride, combinations thereof, or multilayers thereof. A suitable formation method, such as CVD, PECVD, ALD, or the like, may be used to form the dielectric material 141. The dielectric material 141 may fill the notches 132P to form protrusions 141P.

Next, in FIGS. 19A and 19B, a planarization process, such as CMP, is performed to remove the dielectric material 141 and the hard mask layer 131 from the upper surface of the first ILD 114. The remaining portions of the dielectric material 141 in the opening 132 form an isolation structure 141. FIG. 19C shows the top view (e.g., a plan view) of the NSFET device 100. Similar to FIG. 13C, for simplicity, not all features of the NSFET device 100 are illustrated in FIG. 19C. In the illustrated example of FIG. 19C, the isolation structure 141 is disposed between the dielectric plugs 125 along the direction of cross-section A-A, and is disposed between the gate spacers 108 of the gate structure 123B along the direction of cross-section B-B. In the illustrated embodiment of FIG. 19B, the isolation structure 141 and the dielectric plugs 125 separate the gate structure 123B into two separate gate structures 123B1 and 123B2. In addition, the isolation structures 141 isolates (e.g., electrically isolates) the gate structure 123A from the gate structure 123C.

FIG. 19B illustrates dimensions of some of the features in the NSFET device 100, in some embodiments. For example, a gate height A, measured between the upper surface of the topmost nanostructure 54 and the upper surface of the gate electrodes 122, may have a value between about 20.3 nm and about 21.1 nm, with a mean value of about 20.7 nm. A depth D (also referred to as edge maximum height), measured between the upper surface of the topmost nanostructure 54 and the bottom of the protrusion 141P, may have a value between about 151.1 nm and about 157.9 nm, with a mean value of about 154.4 nm. A depth F (also referred to minimum height), measured between the upper surface of the topmost nanostructure 54 and the upper surface 50U1 (see label in FIG. 17B) of the substrate 50, may have a value between about 132.9 nm and about 139.9 nm, with a mean value of about 136.6 nm. In the example of FIG. 19B, the upper surface 50U1 of the substrate 50 is not a flat surface. The notation 50U1 is used to denote a flat portion of the upper surface of the substrate 50, and the upper surface of the substrate 50 may have one or more divots that extends below the flat portion of the upper surface (e.g., 50U1). A depth E (also referred to as center maximum height), measured between the upper surface of the topmost nanostructure 54 and the bottom of the divot in the upper surface 50U1 of the substrate 50, may have a value between about 141.5 nm and about 144.3 nm, with a mean value of about 142.9 nm.

For simplicity, the sidewalls of the dielectric plugs 125 contacting the isolation structure 141 are illustrated as straight lines extending perpendicular to a major upper surface of the substrate 50. In the final product of the NSFET device 100, the sidewalls of the dielectric plugs 125 may not be perfectly straight and/or may not be perfectly perpendicular to the major upper surface of the substrate 50. A width H (also referred to as 1^{st} sheet CD), measured between opposing sidewalls of the dielectric plugs 125 at the upper surface of the topmost nanostructure 54, may have a value between about 147.1 nm and about 152.2 nm, with a mean value of about 149.1 nm. A width I (also referred to as plateau CD), measured between opposing sidewalls of the dielectric plugs 125 at the upper surface of the fin 90A, may have a value between about 148.0 nm and about 152.6 nm, with a mean value of about 150.0 nm. A width G (also referred to as hard mask CD), measured between opposing sidewalls of the dielectric plugs 125 at the upper surface of the gate electrode 122, may have a value between about 140.9 nm and about 146.3 nm, with a mean value of about 143.2 nm.

Although the fins 90 are illustrate as having substantially rectangular cross-sections, the fins 90 may have, e.g., trapezoidal cross-sections. A width J (also referred to as peak-to-peak bottom width), measured between the peaks at the upper surface 50U1 of the substrate 50, may have a value between about 61.9 nm and about 71.3 nm, with a mean value of about 65.9 nm. A width K (also referred to as the trough-to-trough bottom width), measured between the bottoms of the protrusions 141P, may have a value between about 104.4 nm and about 106.1 nm, with a mean value of about 105.4 nm.

Still referring to FIG. 19B, a width IT (also referred to as top metal width), measured between opposing sidewalls of the metal gate 123B2 at the upper surface of the gate electrode 122, may have a value between about 120.5 nm and about 124.2 nm, with a mean value of about 121.9 nm. A width M (also referred to as metal width at 1^{st} sheet), measured between opposing sidewalls of the metal gate 123B2 at the upper surface of the topmost nanostructure 54, may have a value between about 117.3 nm and about 122.9 nm, with a mean value of about 119.8 nm. A width N (also referred to as metal width at plateau), measured between opposing sidewalls of the metal gate 123B2 at the upper surface of the fin 90C, may have a value between about 125.9 nm and about 127.4 nm, with a mean value of about 126.7 nm.

Additional processing may be performed to finish fabrication of the NSFET device 100, as one of ordinary skill readily appreciates, thus details may not be repeated here. For example, a second ILD may be formed over the first ILD 114, and source/drain contacts may be formed to extend through the second ILD and the first ILD 114 to electrically coupled to the source/drain regions 112. Gate contacts may be formed to extend through the second ILD to electrically coupled to the gate structures 123. In addition, interconnect structures that include conductive lines and vias may be formed in the backend-of-the-line (BEOL) processing to interconnect the electrical components formed in/on the substrate 50 to form functional circuits.

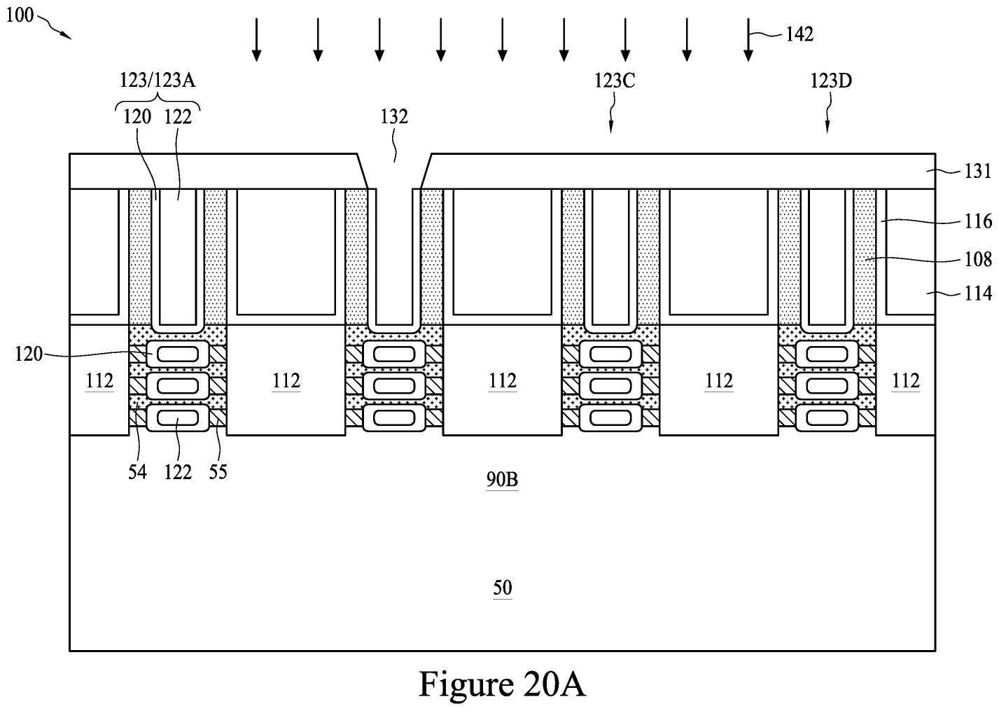

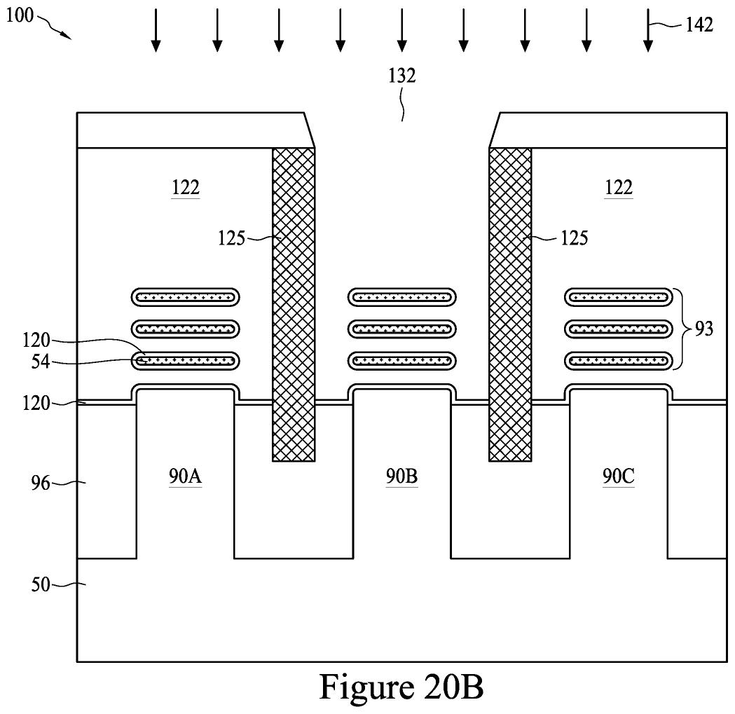

FIGS. 20A and 20B illustrate alternative processing steps to form the NSFET device 100 at a certain stage of manufacturing, in accordance with an embodiment. The processing of FIGS. 20A and 20B follows that of FIGS. 15A and 15B. After the processing of FIGS. 15A and 15B, an etching process, such as a wet etching process using a mild etching solution, is performed to remove he gate electrode 122 in the exposed segment of the gate structure 123B. After the wet etching process, the gate electrode 122 is removed, but the gate dielectric layer 120 remains on the nanostructures 54, as illustrated in FIGS. 20A and 20B. Using the mild etching solution may leave the gate dielectric layer 120 along the sidewalls of the gate spacers 108, which may reduce the likelihood of the wet etching process damaging neighboring metal gate structures, details are discussed hereinafter.

Next, the gate dielectric layer 120 exposed by the opening 132 is removed. In some embodiments, an anisotropic etching process (e.g., a plasma etching process) using a gas source comprising Cl₂, BCl₃, or a combination thereof, is performed to remove the gate dielectric layer 120. After the anisotropic etching process, the nanostructures 54 underlying the opening 132 are exposed.

Next, the plasma dry etching process 143 illustrated in FIGS. 16A and 16B is performed to remove the nanostructures 54. The etching process to remove the nanostructures 154 is the same as or similar to those discussed above, e.g., may include a plurality of etching cycles, with each etching cycle including three sequential processing steps. Details are the same as or similar to those discussed above, thus not repeated here. After the nanostructures 54 are removed, processing follows FIGS. 17A-19C to form the NSFET device 100.

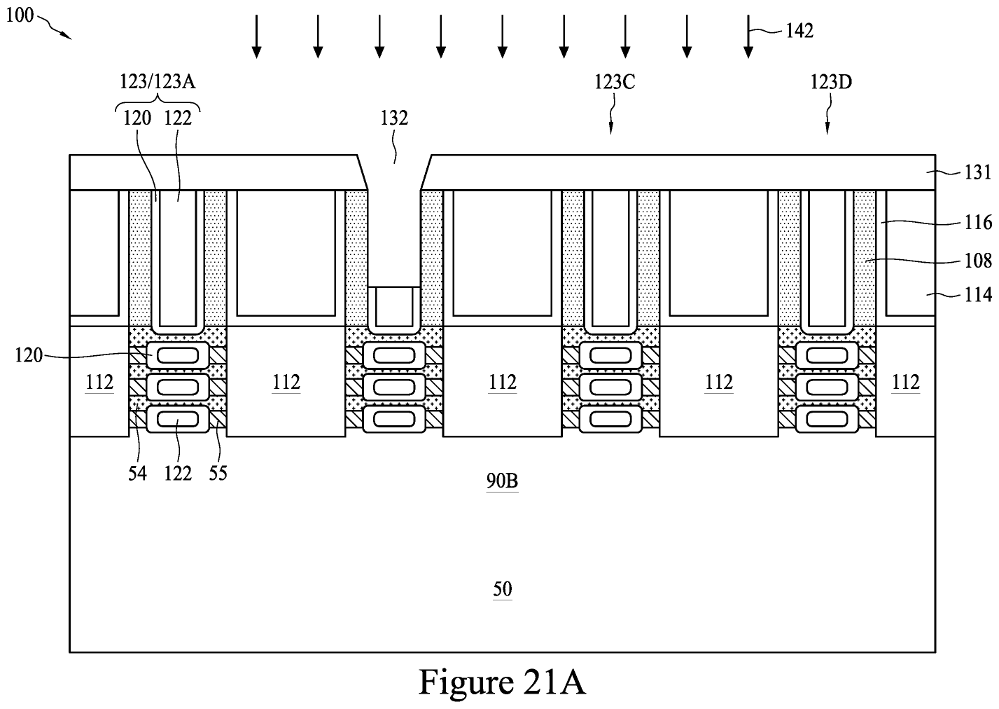

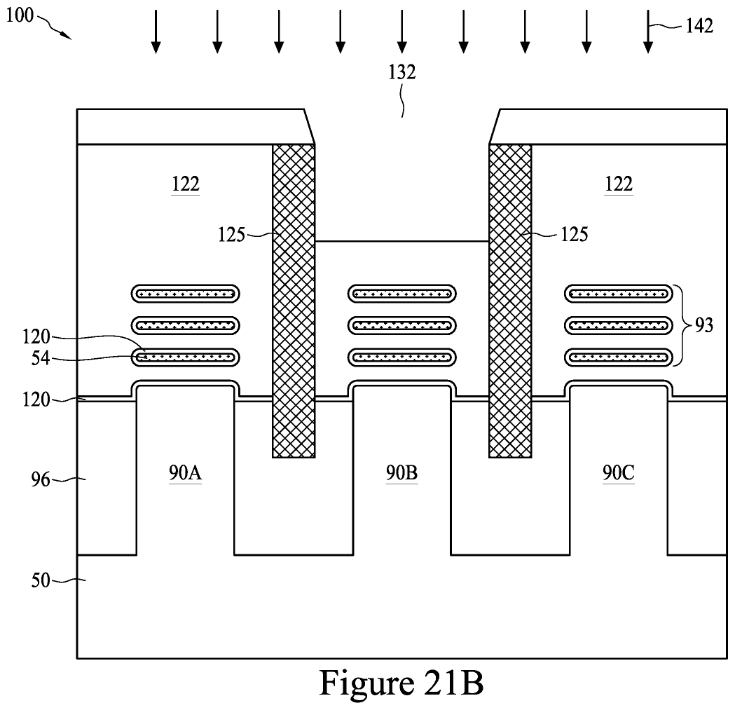

FIGS. 21A and 21B illustrate alternative processing steps to form the NSFET device 100 at a certain stage of manufacturing, in accordance with another embodiment. The processing of FIGS. 21A and 21B follows that of FIGS. 15A and 15B. After the processing of FIGS. 15A and 15B, an etching process, such as a wet etching process, is performed to remove an upper portion of the exposed segment of the gate structure 123B. The wet etching process may be controlled (e.g., timed), such that after the wet etching process, a lower portion of the gate structure 123B remains between the gate spacers 108 and around the nanostructures 54. The wet etching process may use the strong etching solution used in the processing of FIGS. 16A and 16B, or may use the mild etching solution used in the processing of FIGS. 20A and 20B. In embodiments where the mild etching solution is used, the gate dielectric layer 120 may remain on the inner sidewalls of the gate spacers 108. Keeping the lower portion of the gate structure 123B and/or keeping the gate dielectric layer 120 along the inner sidewalls of the gate spacers 108 may reduce the likelihood of the wet etching process damaging neighboring metal gate structures, details are discussed hereinafter.

Next, the lower portion of the gate structure 123B exposed by the opening 132 is removed. In some embodiments, an anisotropic etching process (e.g., a plasma etching process) using a gas source comprising Cl₂, BCl₃, or a combination thereof, is performed to remove the remaining portions of the gate electrode 122 and the gate dielectric layer 120. After the anisotropic etching process, the nanostructures 54 underlying the opening 132 are exposed.

Next, the plasma dry etching process 143 illustrated in FIGS. 16A and 16B is performed to remove the nanostructures 54. The etching process to remove the nanostructures 154 is the same as or similar to those discussed above, e.g., may include a plurality of etching cycles, with each etching cycle including three sequential processing steps. Details are the same as or similar to those discussed above, thus not repeated here. After the nanostructures 54 are removed, processing follows FIGS. 17A-19C to form the NSFET device 100.

Embodiments may achieve advantages. Compared with a Continuous Poly On Diffusion Edge (CPODE) process or a Cut Poly On Diffusion Edge (CPODE) process, where the cutting of the gate structure and the cutting of the nanostructures are performed on the dummy gate structure before the replacement gate structures are formed, the disclosed CMODE method achieve various advantages. For example, in the CMODE method, the wafer on which the NSFET devices 100 are formed has a higher Young's modulus, due to the replacement gate structures (e.g., metal gates) having higher Young's modulus than the dummy gate structures (e.g., polysilicon gates). Therefore, the NSFET device 100 experiences less deformation during the CMODE process, such as during the removal of the segment of gate structure 123B. Since deformation of the NSFEF device 100 may release the stress of the epitaxial source/drain regions 112 (e.g., release stress exerted on the channel regions), less deformation in the NSFET device 100 results in less stress release of the epitaxial source/drain regions 112, thus improving the performance of the NSFET device (e.g., improved carrier mobility in channel regions). In addition, during the etching process to remove the segment of gate structure 123B underlying the opening 132, the hard mask layer 131, the dielectric plugs 125, and the gate spacers 108 define (e.g., delimit) the boundaries of the opening 132 in a self-aligned manner, thus achieving higher tolerance for inaccuracy in the patterning of the hard mask layer 131. Furthermore, the dielectric plugs 125 protects neighboring gate structures 123B1 and 123B2 from being damaged by the etching process used to remove the exposed segment of the gate structure 123B.

The embodiment method illustrated in FIGS. 20A-20B, and 21A-21B offer additional advantage for protecting neighboring gate structures disposed along directions of cross-sections B-B and A-A (e.g., gate structures 123A, 123C, 123B1, and 123B2) from being damaged by the etching process used to remove the exposed segment of the gate structure 123B. Damage to the neighboring gate structures 123A and 123C may happen when the etching solution used in the wet etching process seeps through (e.g., along the direction of cross-section B-B) along interfaces between the hard mask layer 131 and the first ILD 114, or seeps under the source/drain region 112, to reach neighboring gate structures 123A and/or 123C. In addition, damage to the neighboring gate structures 123B1 and 123B2 may happen when the etching solution used in the wet etching process seeps through (e.g., along the direction of cross-section A-A) seams formed in the dielectric plugs 125 to reach neighboring gate structures 123B1 and 123B2. By keeping the gate dielectric layer 120 after the wet etching process, and/or by keeping the lower portion of the gate structure 123B after the wet etching process, the likelihood of the wet etching process damaging neighboring gate structures is greatly reduced, because the gate dielectric layer 120 and/or the lower portion of the gate structure 123B prevent or reduce the likelihood of the etching fluid seeping through to reach the neighboring gate structures.

The above disclosed embodiments use a combination of wet etching process and dry etching process (e.g., plasma dry etching) to remove the exposed segment of the gate structure 123B. In some embodiments, in order to avoid the damage to the neighboring gate structures, the wet etching process is omitted, and anisotropic etching process(es), such as plasma dry etching process, may be used to remove the exposed segment of the gate structure 123B, although this may result in increased processing time.

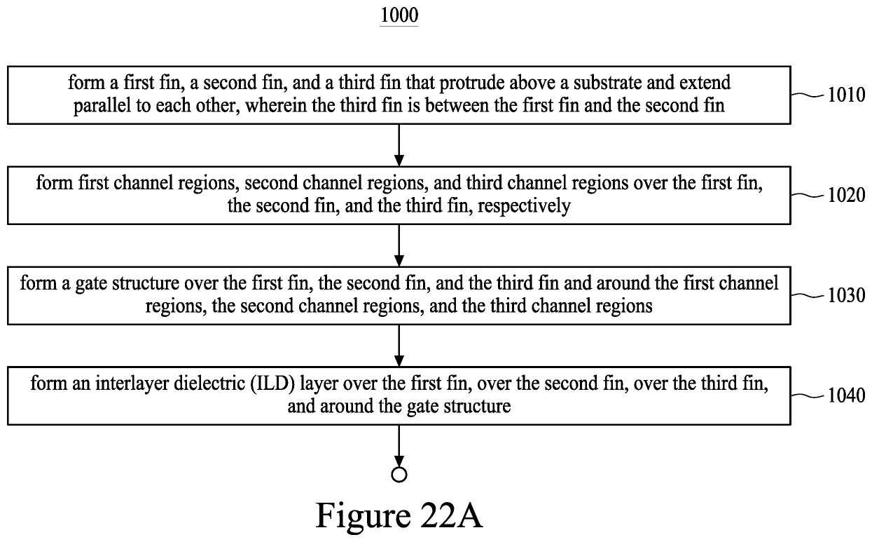

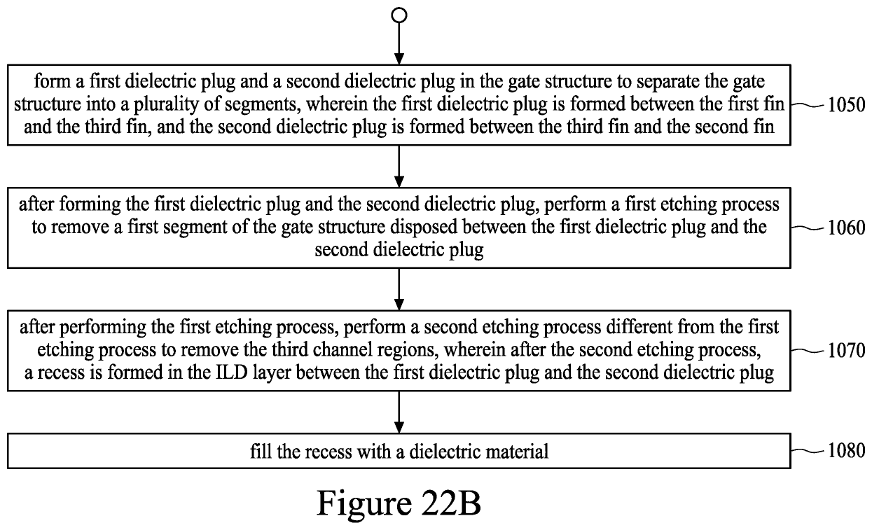

FIGS. 22A and 22B together illustrate a flow chart of a method 1000 of forming a semiconductor device, in accordance with some embodiments. It should be understood that the embodiment method shown in FIGS. 22A and 22B is merely an example of many possible embodiment methods. One of ordinary skill in the art would recognize many variations, alternatives, and modifications. For example, various steps as illustrated in FIGS. 22A and 22B may be added, removed, replaced, rearranged, or repeated.

Referring to FIGS. 22A and 22B, at block 1010, a first fin, a second fin, and a third fin that protrude above a substrate and extend parallel to each other are formed, wherein the third fin is between the first fin and the second fin. At block 1020, first channel regions, second channel regions, and third channel regions are formed over the first fin, the second fin, and the third fin, respectively. At block 1030, a gate structure is formed over the first fin, the second fin, and the third fin and around the first channel regions, the second channel regions, and the third channel regions. At block 1040, an interlayer dielectric (ILD) layer is formed over the first fin, over the second fin, over the third fin, and around the gate structure. At block 1050, a first dielectric plug and a second dielectric plug are formed in the gate structure to separate the gate structure into a plurality of segments, wherein the first dielectric plug is formed between the first fin and the third fin, and the second dielectric plug is formed between the third fin and the second fin. At block 1060, after forming the first dielectric plug and the second dielectric plug, a first etching process is performed to remove a first segment of the gate structure disposed between the first dielectric plug and the second dielectric plug. At block 1070, after performing the first etching process, a second etching process different from the first etching process is performed to remove the third channel regions, wherein after the second etching process, a recess is formed in the ILD layer between the first dielectric plug and the second dielectric plug. At block 1080, the recess is filled with a dielectric material.

In an embodiment, a method of forming a semiconductor device includes: forming a first fin, a second fin, and a third fin that protrude above a substrate and extend parallel to each other, wherein the third fin is between the first fin and the second fin; forming first channel regions, second channel regions, and third channel regions over the first fin, the second fin, and the third fin, respectively; forming a gate structure over the first fin, the second fin, and the third fin and around the first channel regions, the second channel regions, and the third channel regions; forming an interlayer dielectric (ILD) layer over the first fin, over the second fin, over the third fin, and around the gate structure; forming a first dielectric plug and a second dielectric plug in the gate structure to separate the gate structure into a plurality of segments, wherein the first dielectric plug is formed between the first fin and the third fin, and the second dielectric plug is formed between the third fin and the second fin; after forming the first dielectric plug and the second dielectric plug, performing a first etching process to remove a first segment of the gate structure disposed between the first dielectric plug and the second dielectric plug; after performing the first etching process, performing a second etching process different from the first etching process to remove the third channel regions, wherein after the second etching process, a recess is formed in the ILD layer between the first dielectric plug and the second dielectric plug; and filling the recess with a dielectric material. In an embodiment, the gate structure is a replacement gate structure, wherein forming the gate structure comprises: forming a dummy gate structure over the first fin, the second fin, and the third fin and around the first channel regions, the second channel regions, and the third channel regions; forming the ILD layer around the dummy gate structure; removing the dummy gate structure to form an opening in the ILD layer; forming a gate dielectric material in the opening around the first channel regions, the second channel regions, and the third channel regions; and filling the opening with a gate electrode material. In an embodiment, the first etching process is a wet etching process, and the second etching process is a plasma dry etching process. In an embodiment, the recess is formed to expose a first sidewall of the first dielectric plug, a second sidewall of the second dielectric plug, a third sidewall of a first gate spacer, and a fourth sidewall of a second gate spacer, wherein the first gate spacer and the second gate spacer extend along opposing sidewalls of the gate structure. In an embodiment, the second etching process recesses a portion of the third fin underlying the third channel regions, wherein after the second etching process, the recess in the ILD has a downward protrusion that extends into shallow trench isolation (STI) regions below an upper surface of the recessed portion of the third fin, wherein the STI regions surround the first fin, the second fin, and the third fin. In an embodiment, the first etching process removes the first segment of the gate structure and exposes the third channel regions. In an embodiment, the first etching process removes a gate electrode material of the first segment of the gate structure, wherein after the first etching process, a gate dielectric material of the first segment of the gate structure remains around the third channel regions. In an embodiment, the method further comprises, after performing the first etching process and before performing the second etching process, performing a third etching process to remove the gate dielectric material around the third channel regions. In an embodiment, the third etching process is another dry etching process different from the plasma dry etching process. In an embodiment, the first etching process removes an upper portion of the first segment of the gate structure distal from the substrate, wherein after the first etching process, a lower portion of the first segment of the gate structure remains over and around the third channel regions, wherein the lower portion of the first segment of the gate structure fills spaces between the third channel regions. In an embodiment, the method further comprises, after performing the first etching process and before performing the second etching process, performing a third etching process to remove the lower portion of the first segment of the gate structure. In an embodiment, the third etching process is another dry etching process different from the plasma dry etching process, wherein the another dry etching process is a gas dry etching process.

In an embodiment, a method of forming a semiconductor device includes: forming a dummy gate structure over a first fin and around first channel regions that are disposed over the first fin; forming an interlayer dielectric (ILD) layer over the first fin around the dummy gate structure; replacing the dummy gate structure with a gate structure; forming a first dielectric plug and a second dielectric plug in the gate structure on opposing sides of the first fin, wherein the first dielectric plug and the second dielectric plug cut the gate structure into a plurality of segments that are separated from each other; removing a segment of the gate structure interposed between the first dielectric plug and the second dielectric plugs to expose the first channel regions; removing the exposed first channel regions, wherein after removing the exposed first channel regions, a recess is formed in the ILD layer; and filling the recess with a dielectric material. In an embodiment, removing the segment of the gate structure comprises performing a wet etching process, wherein removing the exposed first channel regions comprises performing a plasma dry etching process. In an embodiment, the first fin is disposed between a second fin and a third fin, wherein forming the dummy gate structure comprises forming the dummy gate structure over the first fin, the second fin, and the third fin, wherein the dummy gate structure surrounds the first channel regions over the first fin, surrounds second channel regions over the second fin, and surrounds third channel regions over the third fin. In an embodiment, the method further comprises, after forming the first dielectric plug and the second dielectric plug and before removing the segment of the gate structure: forming a patterned mask layer over the ILD layer and over the gate structure, wherein an opening in the patterned mask layer exposes the segment of the gate structure, wherein the patterned mask layer is used as an etching mask in the wet etching process and the plasma dry etching process. In an embodiment, the plasma dry etching process is performed in a plurality of etching cycles, wherein performing each of the plurality of etching cycles comprises: forming a passivation layer over an upper surface of the patterned mask layer and along sidewalls of the patterned mask layer exposed by the opening; and after forming the passivation layer, performing an anisotropic plasma etching.

In an embodiment, a semiconductor device includes: a substrate; a first fin, a second fin, and a third fin that protrude above the substrate and extend parallel to each other, wherein the third fin is between the first fin and the second fin; first channel regions over the first fin; a first gate structure over the first fin and around the first channel regions; second channel regions over the second fin; a second gate structure over the second fin and around the second channel regions; an isolation structure over the third fin, wherein in a top view, the first gate structure, the second gate structure, and the isolation structure extend along a same line; an interlayer dielectric (ILD) layer over the first fin, the second fin, and the third fin and around the first gate structure, the second gate structure, and the isolation structure; a first dielectric plug in the ILD layer between the first gate structure and the isolation structure; and a second dielectric plug in the ILD layer between the second gate structure and the isolation structure. In an embodiment, the first dielectric plug contacts the first gate structure and the isolation structure, wherein the second dielectric plug contacts the second gate structure and the isolation structure. In an embodiment, the first dielectric plug, the second dielectric plug, the first gate structure, the second gate structure, and the isolation structure have a coplanar upper surface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a first fin, a second fin, and a third fin that protrude above a substrate and extend parallel to each other, wherein the third fin is between the first fin and the second fin;
forming first channel regions, second channel regions, and third channel regions over the first fin, the second fin, and the third fin, respectively;
forming a gate structure over the first fin, the second fin, and the third fin and around the first channel regions, the second channel regions, and the third channel regions;
forming an interlayer dielectric (ILD) layer over the first fin, over the second fin, over the third fin, and around the gate structure;
forming a first dielectric plug and a second dielectric plug in the gate structure to separate the gate structure into a plurality of segments, wherein the first dielectric plug is formed between the first fin and the third fin, and the second dielectric plug is formed between the third fin and the second fin;
after forming the first dielectric plug and the second dielectric plug, performing a first etching process to remove a first segment of the gate structure disposed between the first dielectric plug and the second dielectric plug;
after performing the first etching process, performing a second etching process different from the first etching process to remove the third channel regions, wherein after the second etching process, a recess is formed in the ILD layer between the first dielectric plug and the second dielectric plug; and
filling the recess with a dielectric material.

2. The method of claim 1, wherein the gate structure is a replacement gate structure, wherein forming the gate structure comprises:
forming a dummy gate structure over the first fin, the second fin, and the third fin and around the first channel regions, the second channel regions, and the third channel regions;
forming the ILD layer around the dummy gate structure;
removing the dummy gate structure to form an opening in the ILD layer;
forming a gate dielectric material in the opening around the first channel regions, the second channel regions, and the third channel regions; and
filling the opening with a gate electrode material.

3. The method of claim 1, wherein the first etching process is a wet etching process, and the second etching process is a plasma dry etching process.

4. The method of claim 3, wherein the recess is formed to expose a first sidewall of the first dielectric plug, a second sidewall of the second dielectric plug, a third sidewall of a first gate spacer, and a fourth sidewall of a second gate spacer, wherein the first gate spacer and the second gate spacer extend along opposing sidewalls of the gate structure.

5. The method of claim 4, wherein the second etching process removes portions of the third fin underlying the third channel regions, wherein after the second etching process, the recess in the ILD has a downward protrusion that extends through shallow trench isolation (STI) regions and into the substrate, wherein the STI regions surround the first fin, the second fin, and the third fin.

6. The method of claim 3, wherein the first etching process removes the first segment of the gate structure and exposes the third channel regions.

7. The method of claim 3, wherein the first etching process removes a gate electrode material of the first segment of the gate structure, wherein after the first etching process, a gate dielectric material of the first segment of the gate structure remains around the third channel regions.

8. The method of claim 7, further comprising, after performing the first etching process and before performing the second etching process, performing a third etching process to remove the gate dielectric material around the third channel regions.

9. The method of claim 8, wherein the third etching process is another dry etching process different from the plasma dry etching process.

10. The method of claim 3, wherein the first etching process removes an upper portion of the first segment of the gate structure distal from the substrate, wherein after the first etching process, a lower portion of the first segment of the gate structure remains over and around the third channel regions, wherein the lower portion of the first segment of the gate structure fills spaces between the third channel regions.

11. The method of claim 10, further comprising, after performing the first etching process and before performing the second etching process, performing a third etching process to remove the lower portion of the first segment of the gate structure.

12. The method of claim 11, wherein the third etching process is another dry etching process different from the plasma dry etching process, wherein the another dry etching process is a gas dry etching process.

13. A method of forming a semiconductor device, the method comprising:
forming a dummy gate structure over a first fin and around first channel regions that are disposed over the first fin;
forming an interlayer dielectric (ILD) layer over the first fin around the dummy gate structure;
replacing the dummy gate structure with a gate structure;
forming a first dielectric plug and a second dielectric plug in the gate structure on opposing sides of the first fin, wherein the first dielectric plug and the second dielectric plug cut the gate structure into a plurality of segments that are separated from each other;
removing a segment of the gate structure interposed between the first dielectric plug and the second dielectric plugs to expose the first channel regions;
removing the exposed first channel regions, wherein after removing the exposed first channel regions, a recess is formed in the ILD layer; and
filling the recess with a dielectric material.

14. The method of claim 13, wherein removing the segment of the gate structure comprises performing a wet etching process, wherein removing the exposed first channel regions comprises performing a plasma dry etching process.

15. The method of claim 14, wherein the first fin is disposed between a second fin and a third fin, wherein forming the dummy gate structure comprises forming the dummy gate structure over the first fin, the second fin, and the third fin, wherein the dummy gate structure surrounds the first channel regions over the first fin, surrounds second channel regions over the second fin, and surrounds third channel regions over the third fin.

16. The method of claim 14, further comprising, after forming the first dielectric plug and the second dielectric plug and before removing the segment of the gate structure:
forming a patterned mask layer over the ILD layer and over the gate structure, wherein an opening in the patterned mask layer exposes the segment of the gate structure, wherein the patterned mask layer is used as an etching mask in the wet etching process and the plasma dry etching process.

17. The method of claim 16, wherein the plasma dry etching process is performed in a plurality of etching cycles, wherein performing each of the plurality of etching cycles comprises:
forming a passivation layer over an upper surface of the patterned mask layer and along sidewalls of the patterned mask layer exposed by the opening; and
after forming the passivation layer, performing an anisotropic plasma etching.

18. A semiconductor device comprising:
a substrate;
a first fin, a second fin, and a third fin that protrude above the substrate and extend parallel to each other, wherein the third fin is between the first fin and the second fin;
first channel regions over the first fin;
a first gate structure over the first fin and around the first channel regions;
second channel regions over the second fin;
a second gate structure over the second fin and around the second channel regions;
an isolation structure over the third fin, wherein in a top view, the first gate structure, the second gate structure, and the isolation structure extend along a same line;
an interlayer dielectric (ILD) layer over the first fin, the second fin, and the third fin and around the first gate structure, the second gate structure, and the isolation structure;
a first dielectric plug in the ILD layer between the first gate structure and the isolation structure; and
a second dielectric plug in the ILD layer between the second gate structure and the isolation structure.

19. The semiconductor device of claim 18, wherein the first dielectric plug contacts the first gate structure and the isolation structure, wherein the second dielectric plug contacts the second gate structure and the isolation structure.

20. The semiconductor device of claim 19, wherein the first dielectric plug, the second dielectric plug, the first gate structure, the second gate structure, and the isolation structure have a coplanar upper surface.
